(19) United States
(12) Patent Application Publication
(10) Pub. No.: US 2026/0334257 A1
(43) Pub. Date: Oct. 22, 2026

(54) STRESS PROTECTION STRUCTURES FOR LOW-K DIELECTRIC LAYERS UNDER BONDING PADS AND METHODS FOR FORMING THE SAME

(71) Applicant: Taiwan Semiconductor Manufacturing Company Limited, Hsinchu (TW)

(72) Inventors: Chien Hao Hsu, Zhubei City (TW); Wei-Hsiang Tu, Hsinchu City (TW); Kuo-Chin Chang, Chiayi City (TW); Chen-Shien Chen, Zhubei City (TW); Mirng-Ji Lii, Sinpu Township (TW)

(21) Appl. No.: 19/185,323

(22) Filed: Apr. 22, 2025

(51) Int. Cl. H10W 70/65; H10W 42/00; H10W 70/00; H10W 70/05; H10W 70/60; H10W 90/00; H10W 76/15; H10W 76/47; H10W 76/60

(52) U.S. Cl. CPC H10W 70/65; H10W 42/121; H10W 70/095; H10W 70/099; H10W 70/611; H10W 90/00; H10W 90/401; H10W 90/701; H10W 76/15; H10W 76/47; H10W 76/60

(57) ABSTRACT

A device structure may be provided by forming semiconductor devices on a substrate and performing multiple sequences of metal interconnect formation processes. Each sequence includes depositing a dielectric material, forming cavities within the dielectric material, and forming first metal interconnect structures within the cavities. A first subset of the first metal interconnect structures includes a first vertically-extending electrically conductive path with a first electrically-active metal via structure at a first via level. A second subset includes at least one electrically-floating metallic structure within a frame-shaped area in a plan view. The first electrically-active metal via structure is located at a center portion of the frame-shaped area. Bonding pads are formed over the dielectric material layers and the first metal interconnect structures. A bonding pad may be electrically connected to the first vertically-extending electrically conductive path.

### BACKGROUND

Semiconductor devices have become increasingly complex and miniaturized, requiring advanced packaging technologies to meet the demands of modern electronic systems. A challenge in semiconductor packaging is the potential damage to underlying metal interconnect structures in semiconductor dies. Specifically, mechanical stress generated during the bonding process and the underfill process may induce structural damage in metal interconnect structures. The risk of such structural damages increases in embodiments in which the underlying dielectric material layers include extremely low-k (ELK) dielectric materials.

### BRIEF DESCRIPTION OF FIGURES

Aspects of the present disclosure are best understood from the following detailed description when read with the accompanying figures. The various features of elements may not be drawn to scale, and some elements may be omitted from the drawings for clarity.

FIG. 1A is a top view of a first exemplary structure, which includes a wafer containing an array of semiconductor dies after the formation of semiconductor devices, first dielectric material layers, first metal interconnect structures, and edge-seal ring structures according to an embodiment of the present disclosure. FIG. 1B is a vertical cross-sectional view of the first exemplary structure along the vertical cut plane B - B' of FIG. 1A. FIG. 1C is a top-down view of region C in the first exemplary structure of FIG. 1A. An inset in FIG. 1C illustrates a magnified view of a region within FIG. 1C. FIG. 1D is a magnified view of region D in the first exemplary structure of FIG. 1B.

FIGS. 2A - 2C are sequential perspective views of a region around a subset of first metal interconnect structures (40, 140) during formation of a first electrically conductive path and electrically-floating metallic structures according to an embodiment of the present disclosure.

FIGS. 3A - 3L are perspective views of various configurations of a region around a subset of first metal interconnect structures after formation of a first electrically conductive path and electrically-floating metallic structures according to various embodiments of the present disclosure.

FIG. 4 is a vertical cross-sectional view of a region of the exemplary structure after formation of second dielectric material layers and second metal interconnect structures according to an embodiment of the present disclosure.

FIG. 5 is a vertical cross-sectional view of a region of the exemplary structure after formation of a first dielectric passivation layer and pad openings according to an embodiment of the present disclosure.

FIG. 6 is a vertical cross-sectional view of a region of the exemplary structure after formation of bonding pads according to an embodiment of the present disclosure.

FIG. 7 is a vertical cross-sectional view of a region of the exemplary structure after formation and patterning of a second dielectric passivation layer and a third dielectric passivation layer according to an embodiment of the present disclosure.

FIG. 8A is a vertical cross-sectional view of the exemplary structure after formation of underbump metallization pads according to an embodiment of the present disclosure. FIG. 8B is a top-down view of the exemplary structure of FIG. 8A. FIG. 8C is a magnified view of region C of the exemplary structure of FIG. 8A.

FIG. 9 is a vertical cross-sectional view of the exemplary structure after attaching solder material portions to the underbump metallization pads according to an embodiment of the present disclosure.

FIG. 10 is a vertical cross-sectional view of a semiconductor die according to an embodiment of the present disclosure.

FIG. 11 is a vertical cross-sectional view of a first semiconductor package formed by attaching the semiconductor die to a packaging substrate according to an embodiment of the present disclosure.

FIG. 12 is a vertical cross-sectional view of the first semiconductor package after application of an underfill material portion thereupon according to an embodiment of the present disclosure.

FIG. 13 is a vertical cross-sectional view of the first semiconductor package after attaching a stiffener ring and a lid structure according to an embodiment of the present disclosure.

FIG. 14 is a vertical cross-sectional view of a second semiconductor package assembly including a semiconductor die and an interposer according to an embodiment of the present disclosure.

FIG. 15 is a first flowchart illustrating a sequence of processing steps for manufacturing a device structure according to an embodiment of the present disclosure.

FIG. 16 is a second flowchart illustrating a sequence of processing steps for manufacturing a device structure according to an embodiment of the present disclosure.

### DETAILED DESCRIPTION

The following disclosure provides many different embodiments, or examples, for implementing various features of the provided subject matter. Specific examples of components and arrangements are described below to clarify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. A first physical element is “embedded” with a second physical element if the entire volume of the first element is located within a hypothetical volume defined by a set of hypothetical surfaces having the least total surface area selected from all sets of hypothetical surfaces containing the entirety of the outer surfaces of the second element and topologically homeomorphic to a spherical surface. Such a set of hypothetical surfaces covers each opening, if present, in the outer surfaces with a minimum-area surface segment selected from all possible opening-free surface segments. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range. Unless explicitly stated otherwise, each material portion is presumed to have a homogeneous material composition throughout.

As used herein, removal of a first material is “selective to” a second material if the removal rate of the first material is greater than the removal rate of the second material at least by a factor of 3. Unless otherwise expressly indicated, removal of the first material selectively to the second material implies the possibility of the ratio of the removal rates equal to, or greater than, 3.0, and/or 10, and/or 100, and/or 1,000. As used herein, a first surface and a second surface are “vertically coincident” with each other if the second surface overlies or underlies the first surface and there exists a vertical plane or a substantially vertical plane that includes the first surface and the second surface. A vertical plane is a two-dimensional manifold containing a contiguous set of an uncountable infinity of vertical lines, and has a uniform one-dimensional horizontal cross-sectional shape that is invariant under translation along a vertical direction. The vertical plane may be a Euclidian plane in instances in which the uniform one-dimensional horizontal cross-sectional shape is a line, or may be a non-Euclidian plane in instances in which the uniform one-dimensional shape is not a line. A substantially vertical line is a straight line that deviates from a vertical direction by an angle less than 5 degrees. A substantially vertical plane is a two-dimensional manifold containing a contiguous set of an uncountable infinity of substantially vertical lines and/or vertical lines.

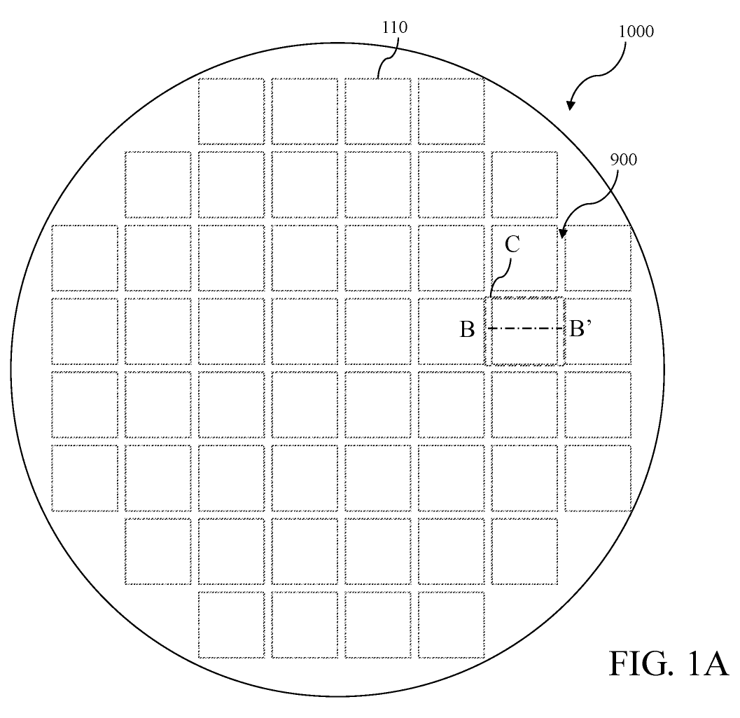

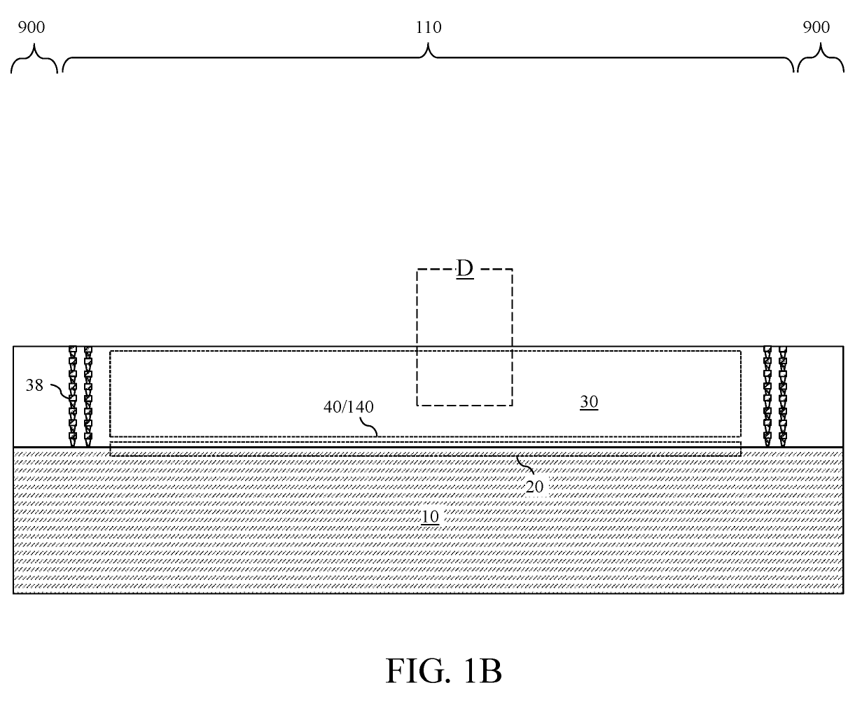

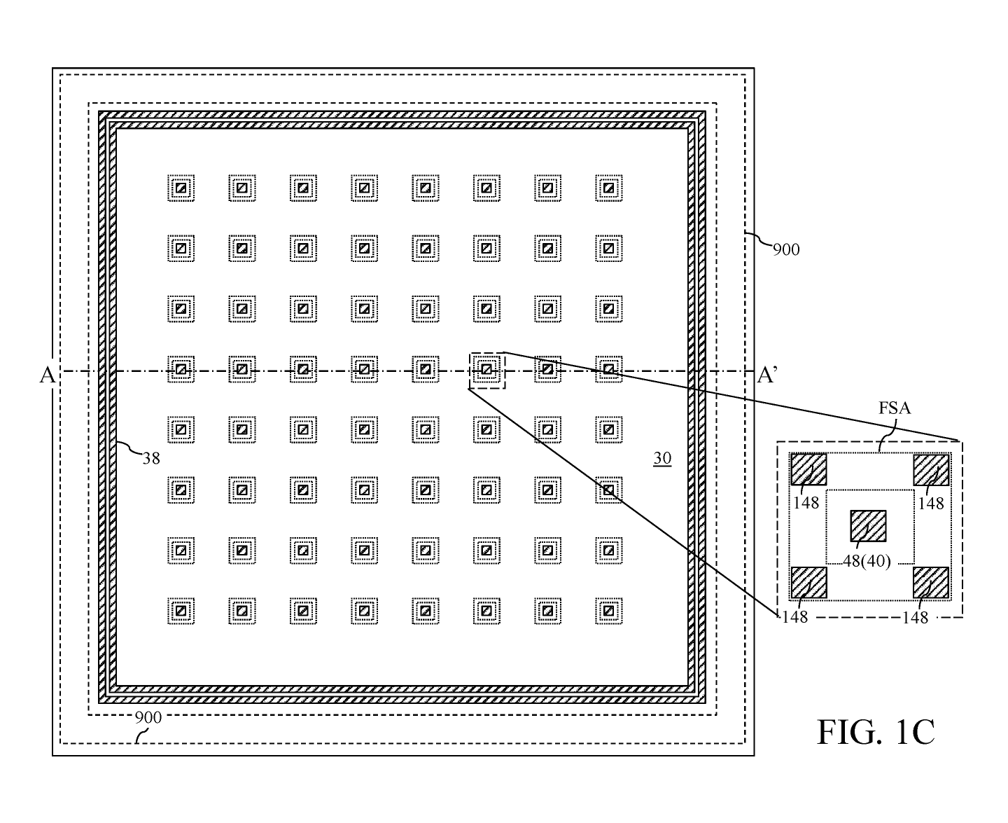

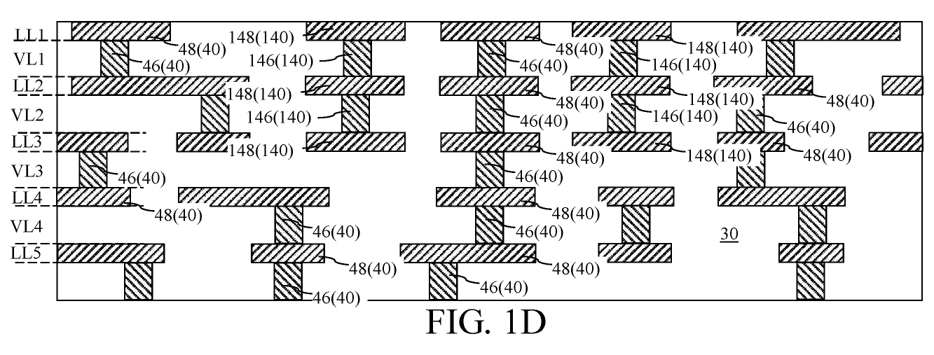

Referring to FIG. 1A, a top-down view of a wafer 1000 is illustrated after formation of semiconductor devices and metal interconnect structures formed within dielectric material layers over a semiconductor substrate. The wafer includes a two-dimensional array of semiconductor die regions 110 and dicing channel region 900. The semiconductor die regions 110 are rectangular portions of the wafer 1000 that become semiconductor dies upon dicing of the wafer 1000 in a subsequent processing step. The dicing channel regions 900 are grid-shaped portions of the wafer 1000 that are removed during the dicing of the wafer 1000.

FIG. 1B is a vertical cross-sectional view of the first exemplary structure along the vertical cut plane B - B' of FIG. 1A. FIG. 1C is a top-down view of region C in the first exemplary structure of FIG. 1A. An inset in FIG. 1C illustrates a magnified view of a region within FIG. 1C. FIG. 1D is a magnified view of region D in the first exemplary structure of FIG. 1B. Referring to FIGS. 1B – 1D, the wafer 1000 comprises a semiconductor substrate 10, which may be a commercially available semiconductor wafer such as a single crystalline wafer. Semiconductor devices 20 may be formed on the semiconductor substrate 10 within each area of the semiconductor die regions 110. The semiconductor devices 20 may comprise any type of semiconductor devices known in the art such as field effect transistors, capacitors, resistors, inductors, diodes, etc.

First dielectric material layers 30 and first metal interconnect structures (40, 140) may be formed over the semiconductor devices 20. The first dielectric material layers 30 comprise interlayer dielectric (ILD) materials known in the art, which may include, for example, undoped silicate glass (USG); doped silicate glasses such as borosilicate glass, borophosphosilicate glass, fluorosilicate glass, etc.; low-k dielectric materials having a dielectric constant in a range from approximately 2.5 to 3.9; ultra-low-k dielectric materials having a dielectric constant in a range from approximately 2.0 to 2.5; and/or extremely-low-k dielectric materials having a dielectric constant in a range from 1.0 to 2.0. Exemplary low-k dielectric materials include fluorine-doped silicon dioxide (FSG) and organosilicate glass (OSG). Exemplary ultra-low-k dielectric materials include porous organosilicate glass and spin-on organic polymers such as benzocyclobutene (BCB). Exemplary extremely-low-k dielectric materials include air gap structures and certain porous materials with high air content. In one embodiment,

The first metal interconnect structures (40, 140) may be formed within the first dielectric material layers 30. The first metal interconnect structures (40, 140) comprise first electrically-active metallic structures 40 and electrically-floating metallic structures 140. As used herein, an “electrically-active” metallic structure may refer to a metallic structure that is electrically connected to at least one electrical node configured to transmit, and/or to receive, an electrical signal and/or an electrical bias voltage. The electrical connection may be through an electrically conductive path, through intended capacitive coupling, or through intended inductive coupling. As used herein, an “electrically-isolated” metallic structure refers to a metallic structure that is electrically isolated from any other electrical node with the exception of unintended parasitic capacitive coupling and/or unintended parasitic inductive coupling. A seal ring 38 may form a perimeter of each region C.

The first dielectric material layers 30 and first metal interconnect structures (40, 140) may be formed through multiple sequences of metal interconnect formation processes. Each sequence may include a dielectric material deposition step that deposits a respective first dielectric material that forms a first dielectric material layer 30 (which is one of the first dielectric material layers 30), a dielectric material patterning step that patterns the respective first dielectric material to form a respective set of cavities, and a metallic structure formation step that deposits and patterns at least one metal to form a respective subset of the first metal interconnect structures (40, 140) within the respective set of cavities. In one embodiment, one or more, and/or each of, the first dielectric material layers 30 comprise, and/or consist essentially of, a respective dielectric materials having a respective dielectric constants between 1.0 and 3.0. In one embodiment, one or more, and/or each of, the first dielectric material layers 30 comprise, and/or consist essentially of, a respective dielectric materials having a respective dielectric constants between 1.0 and 2.0. In one embodiment, one or more, and/or each of, the first dielectric material layers 30 may comprise a respective vertical stack of a porous dielectric material having a respective dielectric constants between 1.0 and 2.0, and a non-porous dielectric material having a higher dielectric constant than the porous dielectric material. In this embodiment, the volume fraction of the porous dielectric material relative to the entire volume of a respective first dielectric material layer 30 may be in a range from 30 % to 90 %, although lesser or greater volume fractions may also be used.

Each set of cavities formed by a respective dielectric material patterning step may comprise line cavities, via cavities, and/or integrated line-and-via cavities. Accordingly, each metallic structure formation step may form metallic line structures (48, 148), metallic via structures (46, 146), and/or integrated metallic line-and-via structures {(48, 46), (148, 146)}. The metallic line structures (48, 148) comprise electrically-active metallic line structures 48 and electrically-floating metallic line structures 148. The metallic via structures (46, 146) comprise electrically-active metallic via structures 46 and electrically-floating metallic via structures 146. In embodiments in which integrated metallic line-and-via structures {(48, 46), (148, 146)} are used, the integrated metallic line-and-via structures {(48, 46), (148, 146)} may comprise electrically-active integrated metallic line-and-via structures (48, 46) and electrically-floating integrated metallic line-and-via structures (148, 146).

In embodiments in which a sequence of metal interconnect formation processes comprises a single damascene process flow, a set of metallic line structures (48, 148) located at a line level may be formed, or a set of metallic via structures (46, 146) located at a via level may be formed. In embodiments in which a sequence of metal interconnect formation processes comprises a dual damascene process, a set of integrated metallic line-and-via structures {(48, 46), (148, 146)} extending over a line level and a via level may be formed. Generally, each sequence of metal interconnection formation processes forms a set of electrically-active metallic line structures 48, a set of electrically-active metallic via structures 46, or a set of electrically-active integrated metallic line-and-via structures (48, 46).

A subset of the electrically-floating metallic line structures 148, a subset of the electrically-floating metallic via structures 146, and/or a subset of the electrically-active integrated metallic line-and-via structures (148, 146) are formed at the topmost line level (which is herein referred to as a first line level LL1) within the first dielectric material layers 30, at the topmost via level (which is herein referred to as a first via level VL1) within the first dielectric material layers 30, and at the second-topmost line level (which is herein referred to as a second line level LL2) within the first dielectric material layers 30. Optionally, an additional subset of the electrically-floating metallic line structures 148, an additional subset of the electrically-floating metallic via structures 146, and/or an additional subset of the electrically-active integrated metallic line-and-via structures (148, 146) are formed at the second-topmost via level (which is herein referred to as a second via level VL1) within the first dielectric material layers 30, and at the third-from-the-top line level (which is herein referred to as a third line level LL3) within the first dielectric material layers 30.

Generally, the electrically-floating metallic structures 140 may be formed in the topmost 2N levels or in the topmost (2N+1) levels, in which N is a positive integer. In embodiments in which the electrically-floating metallic structures 140 are formed in the topmost 2N levels, the topmost 2N levels include each line level between the first line level LL1 and the N-th line level as counted downward from the top, and each via level between the first via level VL1 and the N-th via level as counted downward from the top. In embodiments in which the electrically-floating metallic structures 140 are formed in the topmost (2N+1) levels, the topmost (2N+1) levels include each line level between the first line level LL1 and the (N+1)-th line level as counted downward from the top, and each via level between the first via level VL1 and the N-th via level as counted downward from the top. While FIG. 1C illustrates an embodiment in which the electrically-floating metallic structures 140 are formed in the first line level LL1, the first via level VL1, the second line level LL2, the second via level VL2, and the third line level LL3, embodiments are expressly contemplate herein in which the bottommost level of the electrically-floating metallic structures 140 may be the second line level LL2, the second via level VL2, the third via level VL3, the fourth line level LL4, the fourth via level VL4, the fifth level LL5, or any other underlying level.

According to an aspect of the present disclosure, a first subset of the electrically-active metallic structures 40 forms first vertically-extending electrically conductive paths ECP1. The first vertically-extending electrically conductive paths ECP1 vertically extend through each level through which the electrically-floating metallic structures 140 vertically extend. In one embodiment, a two-dimensional array of first vertically-extending electrically conductive path ECP1 may be formed within each semiconductor die region 110. Some, or all, of the vertically-extending electrically conductive path ECP1 may vertically extend through each first dielectric material layer 30 selected from the first dielectric material layers 30, and may be electrically connected to a respective electrical node selected from the semiconductor devices 20. In some embodiments, semiconductor devices or passive devices may be embedded within a subset of the first dielectric material layers 30 below the levels of the electrically-floating metallic structures 140, and a subset of the first vertically-extending electrically conductive path ECP1 may be electrically connected to a respective node of the semiconductor devices or passive devices that are embedded within the first dielectric material layers 30.

According to an aspect of the present disclosure, a second subset of the first metal interconnect structures (40, 140) comprises at least one electrically-floating metallic structure 140 that is formed around a respective contiguous subset of the electrically-active metallic structures 40 that defines an upper portion of a respective first vertically-extending electrically conductive path ECP1. In one embodiment, the at least one electrically-floating metallic structure 140 around the respective contiguous subset of the electrically-active metallic structures 40 may be formed within a respective frame-shaped area. In this embodiment, the upper portion of the respective first vertically-extending electrically conductive path ECP1 may be formed entirely within the area bounded by an inner periphery of the frame-shaped area.

As used herein, a “frame-shaped area” refers to an area located between an inner periphery and an outer periphery that is laterally offset outward from the inner periphery. The lateral offset distance between the inner periphery and the outer periphery may be uniform or non-uniform. The shape of the inner periphery and the shape of the outer periphery may be any two-dimensional shape having a single closed periphery. According to an aspect of the present disclosure, the upper portion of the respective first vertically-extending electrically conductive path ECP1 comprises at least one electrically-active metal via structure 46, and each of the at least one electrically-active metal via structure 46 is formed entirely within the inner periphery of the frame-shaped area (FSA) in the plan view.

In one embodiment, the upper portion of the respective first vertically-extending electrically conductive path ECP1 may comprise a first electrically-active metal via structure 46 that is formed at a first via level VL1 (which is the topmost via level of the first dielectric material layers 30), any may optionally comprise a second electrically-active metal via structure 46 that is formed at a second via level VL2 that underlies the first via level VL1, and may optionally comprise one or more additional electrically-active metal via structures 46 that are formed below the second via level.

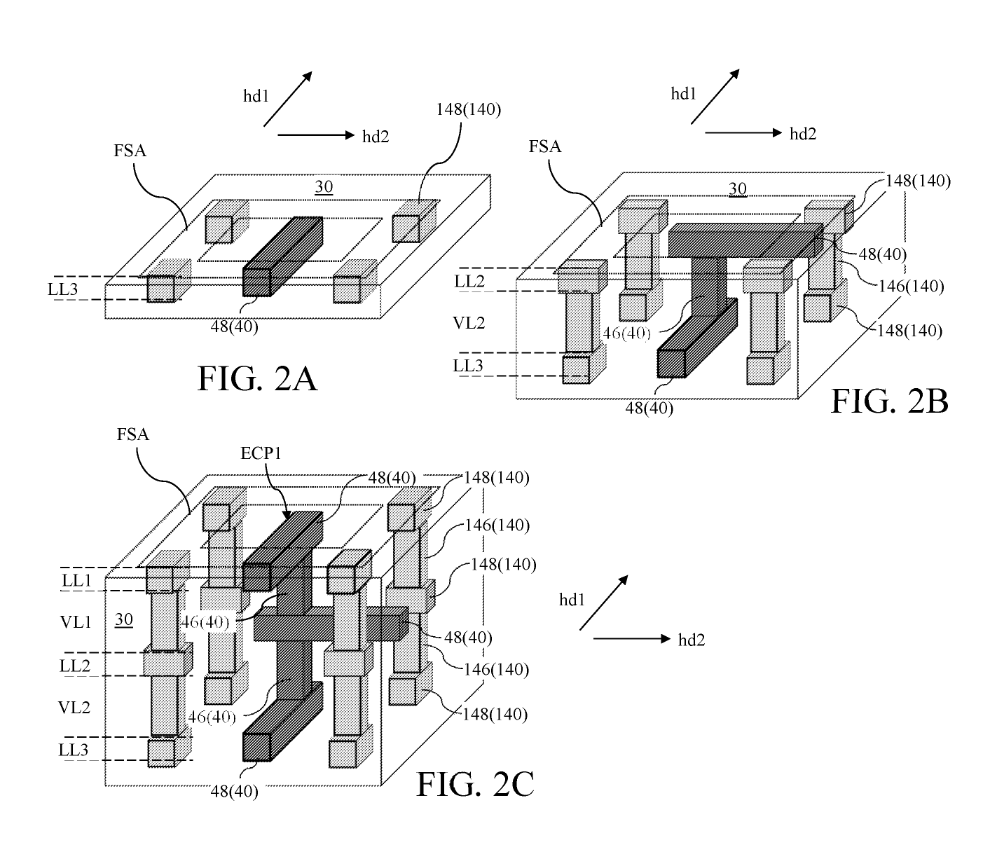

Referring to FIGS. 2A - 2C, sequential perspective views of a region around a subset of first metal interconnect structures (140, 40) are illustrated during formation of a first electrically conductive path ECP1 and electrically-floating metallic structures 140 therearound according to an embodiment of the present disclosure.

Referring to FIG. 2A, a region around an upper portion of a first electrically conductive path ECP1 to be subsequently formed is illustrated after formation of a first dielectric material layer 30 for a line level, which is the third topmost line level selected from the line levels within the set of all first dielectric material layers 30 to be formed. The third topmost line level is herein referred to as a third line level LL3. A first electrically-active metal line 48 and multiple electrically-floating metal lines 148 may be formed within the first dielectric material layer in the third line level LL3.

Referring to FIG. 2B, at least one additional first dielectric material layer 30 may be deposited for a via level and for an additional line level. The via level may be a second topmost via level within the set of all first dielectric material layers 30 to be formed, and is herein referred to as a second via level VL2. The additional line level may be a second topmost line level selected from the line levels within the set of all first dielectric material layers 30 to be formed. The second topmost line level is herein referred to as a second line level LL2. A first electrically-active metal line 48, a first electrically-active metal via structure 46, multiple electrically-floating metal lines 148, and multiple electrically-floating metal via structures 146 may be formed within the at least one additional first dielectric material layer 30 in the second via level VL2 and the second line level LL2.

Referring to FIG. 2C, at least one additional first dielectric material layer 30 may be deposited for a via level and for an additional line level. The via level may be a topmost via level within the set of all first dielectric material layers 30 to be formed, and is herein referred to as a first via level VL1. The additional line level may be a topmost line level selected from the line levels within the set of all first dielectric material layers 30 to be formed. The topmost line level is herein referred to as a first line level LL1. A first electrically-active metal line 48, a first electrically-active metal via structure 46, multiple electrically-floating metal lines 148, and multiple electrically-floating metal via structures 146 may be formed within the at least one additional first dielectric material layer 30 in the first via level VL1 and the first line level LL1.

A frame-shaped area (FSA) may be defined based on the areas of a set of electrically-floating metallic structures 140 around an upper portion of the first electrically conductive path ECP1 that includes a first electrically-active metal via structure 46. Specifically, the frame-shaped area (FSA) may be defined to include all area of the set of electrically-floating metallic structures 140 around the first electrically conductive path ECP1 in a plan view (i.e., a view along a vertical direction), while excluding the areas of all electrically-active metallic via structures 46 within the upper portion of the first electrically conductive path ECP1 that is formed in the third line level LL3 and above.

In embodiments in which the first electrically-active metallic structures 40 and the electrically-floating metallic structures 140 comprise first sidewalls that are parallel to a first horizontal direction hd1 and second sidewalls that are parallel to a second horizontal direction hd2, the FSA may be a rectangular frame-shaped area including a rectangular outer periphery and a rectangular inner periphery. In one embodiment, the frame-shaped area may have an outer rectangular periphery that coincides with a subset of sidewalls of the at least one electrically-floating metallic structure 140. The FSA may further comprise an inner rectangular periphery that coincides with at least one vertically-extending edge of the at least one electrically-floating metallic structure 140. An entire area of the at least one electrically-floating metallic structure 140 may be formed within the FSA. The first electrically-active metal via structure 46 may be laterally offset inward from the inner rectangular periphery of the FSA.

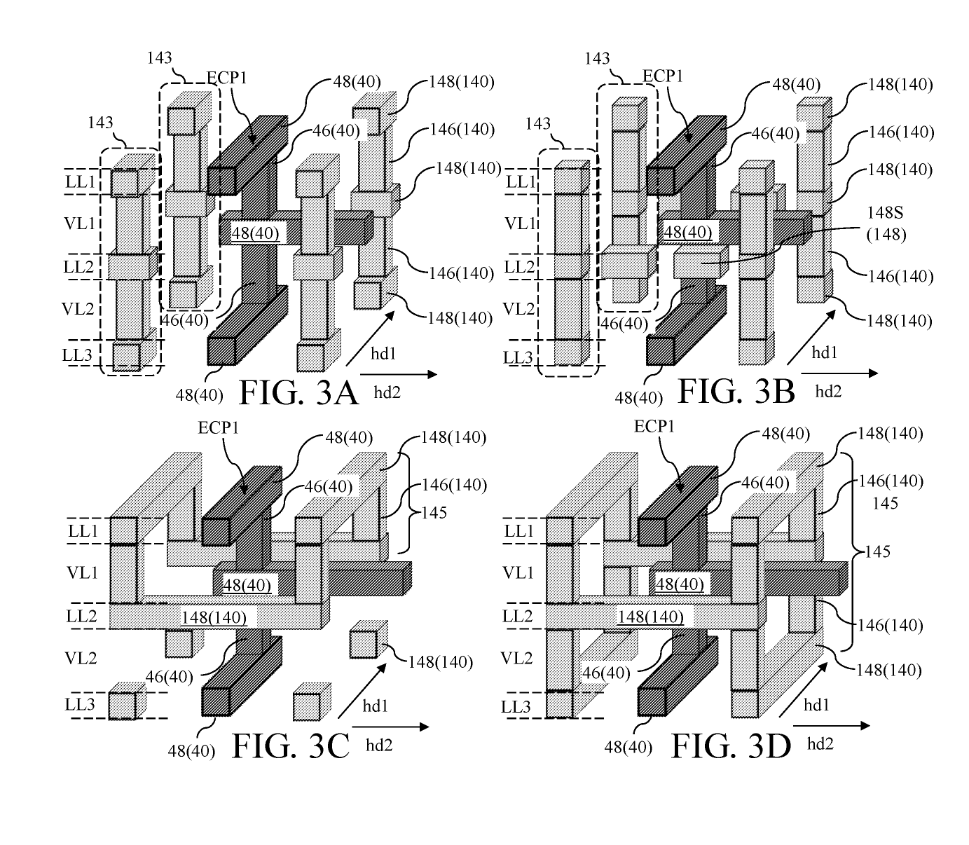

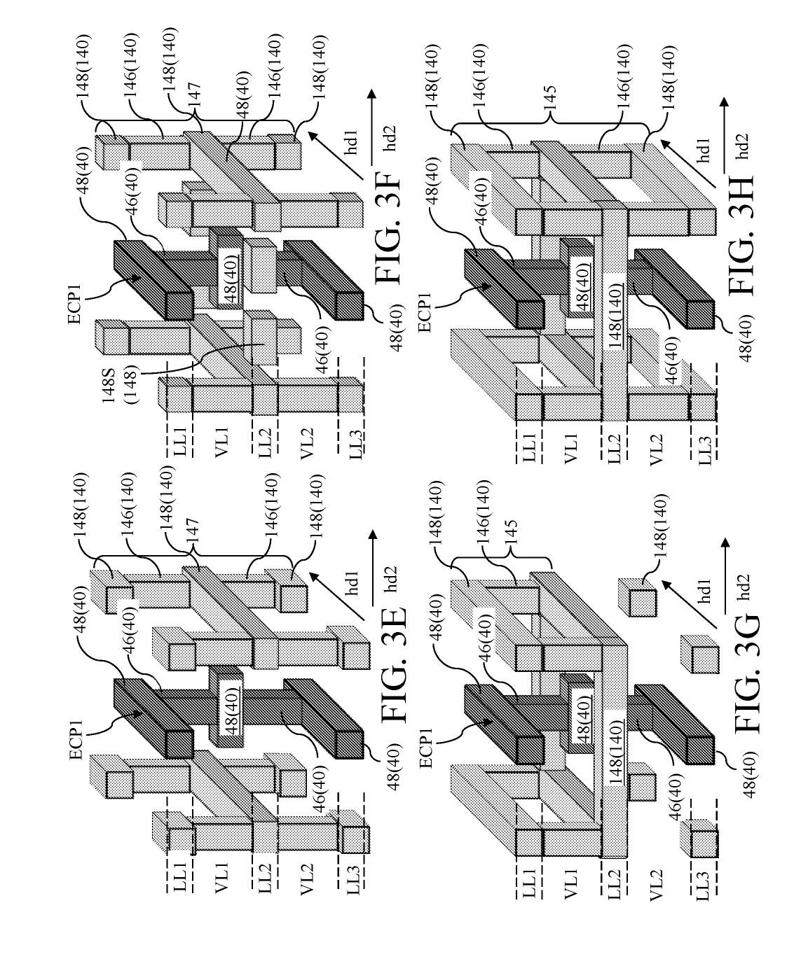

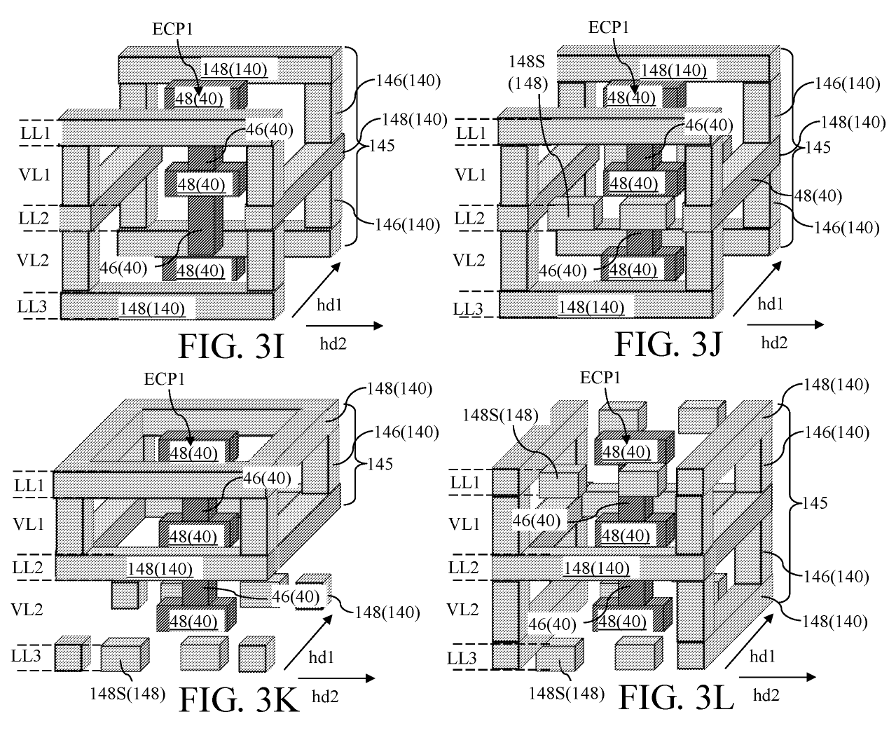

FIGS. 3A - 3L are perspective views of various configurations of a region around a subset of first metal interconnect structures (40, 140) after formation of a first electrically conductive path ECP1 and electrically-floating metallic structures 140 according to various embodiments of the present disclosure.

Referring to FIG. 3A, a first configuration for a first electrically-active path ECP1 and at least one electrically-floating metallic structure 140 is illustrated. The at least one electrically-floating metallic structure 140 may comprise a plurality of electrically-floating metallic structures 140 that are spaced apart from one another. In the first configuration, the at least one electrically-floating metallic structure 140 is formed as a plurality of electrically-floating metallic assemblies 143 each comprising a respective vertical stack of an electrically-floating metal via structure 146 located at a first via level VL1, a first electrically-floating metal line 148 located at a first line level LL1, a second electrically-floating metal line 148 located at a second line level LL2, and optionally an additional electrically-floating metal via structure 146 located at a second via level VL2, and an additional electrically-floating metal line 148 located at a third line level LL3. In one embodiment, each of the plurality of electrically-floating metallic assemblies 143 may be located within a respective corner region of the FSA in the plan view.

Generally, all electrically-active metal via structures 46 within the first electrically-active metallic structures 40 in a first electrically conductive path ECP1 that are located at the levels of the at least one electrically-floating metallic structure 140 is located entirely within an inner periphery of a respective FSA. The electrically-active metal lines 48 within the first electrically-active metallic structures 40 in the first electrically conductive path ECP1 located at the levels of the at least one electrically-floating metallic structure 140 may be located entirely within the inner periphery of the respective FSA. Alternatively, the electrically-active metal lines 48 within the first electrically-active metallic structures 40 in the first electrically conductive path ECP1 located at the levels of the at least one electrically-floating metallic structure 140 may be located partly within the FSA, and may be located partly outside an outer periphery of the frame-shaped area FSA. In other words, the electrically-active metal lines 48 may laterally extend into the FSA, and/or may extent outside the outer periphery of the FSA.

Referring to FIG. 3B, a second configuration for the first electrically-active path ECP1 and the at least one electrically-floating metallic structure 140 is illustrated. The second configuration may be derived from the first configuration by forming sidewall metal lines 148S along a peripheral region of the FSA. The sidewall metal lines 148S are additional electrically-floating metal lines 148 laterally extending along the first horizontal direction hd1 or along the second horizontal direction hd2, and formed at a line level, which may be the first line level LL2, the second line level LL2, or the third line level LL3. In one embodiment, the FSA may comprise a rectangular frame-shaped area, and the at least one electrically-floating metallic structure 140 may comprise a plurality of sidewall metal lines 148S that are arranged along sides of an outer rectangular periphery of the FSA in the plan view and laterally spaced apart from one another.

Referring to FIG. 3C, a third configuration for the first electrically-active path ECP1 and the at least one electrically-floating metallic structure 140 is illustrated. The third configuration comprises a frame-shaped interconnected metallic assembly 145 extending around a peripheral portion of the FSA in the plan view. The frame-shaped interconnected metallic assembly 145 is a contiguous subset of the electrically-floating metallic structures 140 that includes a pair of first electrically-floating metal lines 148 laterally extending along a first horizontal direction hd1 and a pair of second electrically-floating metal lines 148 laterally extending along a second horizontal direction hd2.

Generally, the pair of first electrically-floating metal lines 148 laterally extending along the first horizontal direction hd1 and the pair of second electrically-floating metal lines 148 laterally extending along the second horizontal direction hd2 may be located at a same line level, or may be located at different line levels. In an illustrative example, the pair of first electrically-floating metal lines 148 laterally extending along the first horizontal direction hd1may be formed in the first line level LL1, and the pair of second electrically-floating metal lines 148 laterally extending along the second horizontal direction hd2 may be formed in the second line level LL2. In one embodiment, the frame-shaped interconnected metallic assembly 145 may further include four electrically-floating metal via structures 146. Each electrically-floating metal via structure 146 may connect a respective first electrically-floating metal line 148 in the first line level LL1 to a respective second electrically-floating metal line 148 in the second line level LL2. The frame-shaped interconnected metallic assembly 145 is a continuous frame-like structure located around the periphery of the FSA, and may span multiple line levels. Discrete first electrically-floating metal lines 148 may be provided at corner regions of the FSA. Further, sidewall metal lines (not illustrated) may be present along one or more sides of the FSA in the plan view.

Referring to FIG. 3D, a fourth configuration for the first electrically-active path ECP1 and the at least one electrically-floating metallic structure 140 is illustrated. The fourth configuration comprises a frame-shaped interconnected metallic assembly 145 extending around a peripheral portion of the FSA in the plan view. The frame-shaped interconnected metallic assembly 145 is a contiguous subset of the electrically-floating metallic structures 140 that includes three or more pairs of first electrically-floating metal lines 148. Each pair of electrically-floating metal lines 148 may laterally extend along a first horizontal direction hd1 or a second horizontal direction hd2.

In an illustrative example, a pair of first electrically-floating metal lines 148 laterally extending along the first horizontal direction hd1 may be formed in the first line level LL1, a pair of second electrically-floating metal lines 148 laterally extending along the second horizontal direction hd2 may be formed in the second line level LL2, and a pair of third electrically-floating metal lines 148 laterally extending along the first horizontal direction hd1 may be formed at the third line level LL3. In one embodiment, the frame-shaped interconnected metallic assembly 145 may further include electrically-floating metal via structures 146 providing vertical structural connections to and from the electrically-floating metal lines 148. The frame-shaped interconnected metallic assembly 145 is a continuous frame-like structure located around the periphery of the FSA, and may span multiple line levels.

Referring to FIG. 3E, a fifth configuration for the first electrically-active path ECP1 and the at least one electrically-floating metallic structure 140 is illustrated. The fifth configuration comprises at least one scaffold-wall-shaped interconnected metallic assembly 147 located at a respective side of the FSA in the plan view, and vertically extending over at least two line levels, which may be at least three line levels. Each scaffold-wall-shaped interconnected metallic assembly 147 may be located between a neighboring pair of a side of an inner periphery of a rectangular frame-shaped area and a side of an outer periphery of the rectangular frame-shaped area. Each scaffold-wall-shaped interconnected metallic assembly 147 may be a respective contiguous subset of the electrically-floating metallic structures 140 that includes two or more first electrically-floating metal lines 148. In the fifth configuration, a first electrically-active metal line 48 may be located entirely within an inner periphery of the FSA in the plan view. For example, the first electrically-active metal line 48 at the second line level LL2 may be located entirely within the inner periphery of the FSA in the plan view.

Referring to FIG. 3F, a sixth configuration for the first electrically-active path ECP1 and the at least one electrically-floating metallic structure 140 is illustrated. The sixth configuration may be derived from the fifth configuration by forming sidewall metal lines 148S along a peripheral region of the FSA.

Referring to FIG. 3G, a seventh configuration for the first electrically-active path ECP1 and the at least one electrically-floating metallic structure 140 is illustrated. The seventh configuration comprises a frame-shaped interconnected metallic assembly 145 extending over two line levels and a via level. The seventh configuration may further comprise discrete first electrically-floating metal lines 148 formed at corner regions of the FSA. In the seventh configuration, a first electrically-active metal line 48 may be located entirely within an inner periphery of the FSA in the plan view. For example, the first electrically-active metal line 48 at the second line level LL2 may be located entirely within the inner periphery of the FSA in the plan view.

Referring to FIG. 3H, an eighth configuration for the first electrically-active path ECP1 and the at least one electrically-floating metallic structure 140 is illustrated. The eighth configuration comprises a frame-shaped interconnected metallic assembly 145 extending over three line levels and two via levels. In the eighth configuration, a first electrically-active metal line 48 may be located entirely within an inner periphery of the FSA in the plan view. For example, the first electrically-active metal line 48 at the second line level LL2 may be located entirely within the inner periphery of the FSA in the plan view.

Referring to FIG. 3I, a ninth configuration for the first electrically-active path ECP1 and the at least one electrically-floating metallic structure 140 is illustrated. The ninth configuration comprises a frame-shaped interconnected metallic assembly 145 extending around a peripheral portion of the FSA in the plan view. The frame-shaped interconnected metallic assembly 145 is a contiguous subset of the electrically-floating metallic structures 140 that includes a pair of first electrically-floating metal lines 148 laterally extending along a first horizontal direction hd1 and a pair of second electrically-floating metal lines 148 laterally extending along a second horizontal direction hd2. In the ninth configuration, each first electrically-active metal line 48 overlying a bottommost surface of a frame-shaped interconnected metallic assembly may be located entirely within an inner periphery of the FSA in the plan view. In one embodiment, the frame-shaped interconnected metallic assembly 145 includes three or more pairs of first electrically-floating metal lines 148. Each pair of electrically-floating metal lines 148 may laterally extend along a first horizontal direction hd1 or a second horizontal direction hd2.

In an illustrative example, a pair of first electrically-floating metal lines 148 laterally extending along the first horizontal direction hd1 may be formed in the first line level LL1, a pair of second electrically-floating metal lines 148 laterally extending along the second horizontal direction hd2 may be formed in the second line level LL2, and a pair of third electrically-floating metal lines 148 laterally extending along the first horizontal direction hd1 may be formed at the third line level LL3. In one embodiment, the frame-shaped interconnected metallic assembly 145 may further include electrically-floating metal via structures 146 providing vertical structural connections to and from the electrically-floating metal lines 148. The frame-shaped interconnected metallic assembly 145 is a continuous frame-like structure located around the periphery of the FSA, and may span multiple line levels. The electrically-active metal lines 48 within the first electrically-active metallic structures 40 in the first electrically conductive path ECP1 located at the levels of the at least one electrically-floating metallic structure 140 may be located entirely within the inner periphery of the respective FSA.

Referring to FIG. 3J, a tenth configuration for the first electrically-active path ECP1 and the at least one electrically-floating metallic structure 140 is illustrated. The tenth configuration may be derived from the ninth configuration by forming sidewall metal lines 148S along a peripheral region of the FSA. The sidewall metal lines 148S are additional electrically-floating metal lines 148 laterally extending along the first horizontal direction hd1 or along the second horizontal direction hd2, and formed at a line level, which may be the first line level LL2, the second line level LL2, or the third line level LL3. In one embodiment, the FSA may comprise a rectangular frame-shaped area, and the at least one electrically-floating metallic structure 140 may comprise a plurality of sidewall metal lines 148S that are arranged along sides of an outer rectangular periphery of the FSA in the plan view and laterally spaced apart from one another.

Referring to FIG. 3K, an eleventh configuration for the first electrically-active path ECP1 and the at least one electrically-floating metallic structure 140 is illustrated. The eleventh configuration comprises a frame-shaped interconnected metallic assembly 145 extending around a peripheral portion of the FSA in the plan view. The frame-shaped interconnected metallic assembly 145 is a contiguous subset of the electrically-floating metallic structures 140 that includes at least one pair of first electrically-floating metal lines 148 laterally extending along a first horizontal direction hd1 and at least one pair of second electrically-floating metal lines 148 laterally extending along a second horizontal direction hd2.

In one embodiment, multiple pairs of first electrically-floating metal lines 148 laterally extending along the first horizontal direction hd1 may be located in multiple line levels, and/or multiple pairs of second electrically-floating metal lines 148 laterally extending along the second horizontal direction hd2 may be located in multiple levels. In an illustrative example, a first pair of first electrically-floating metal lines 148 laterally extending along the first horizontal direction hd1 may be formed in the first line level LL1, a second pair of first electrically-floating metal lines 148 laterally extending along the first horizontal direction hd1 may be formed in the second line level LL2, a first pair of second electrically-floating metal lines 148 laterally extending along the second horizontal direction hd2 may be formed in the first line level LL1, and a second pair of second electrically-floating metal lines 148 laterally extending along the second horizontal direction hd2 may be formed in the second line level LL2. In one embodiment, the frame-shaped interconnected metallic assembly 145 may further include multiple electrically-floating metal via structures 146. Each electrically-floating metal via structure 146 may connect a respective first electrically-floating metal line 148 to a respective second electrically-floating metal line 148 located in a different level. The frame-shaped interconnected metallic assembly 145 is a continuous frame-like structure located around the periphery of the FSA, and may span multiple line levels. Discrete first electrically-floating metal lines 148 may be provided at corner regions of the FSA. Further, sidewall metal lines 148S may be present along one or more sides of the FSA in the plan view.

Referring to FIG. 3L, a twelfth configuration for the first electrically-active path ECP1 and the at least one electrically-floating metallic structure 140 is illustrated. The twelfth configuration comprises a frame-shaped interconnected metallic assembly 145 extending over three line levels and two via levels. In the twelfth configuration, each first electrically-active metal line 48 overlying a bottommost surface of a frame-shaped interconnected metallic assembly may be located entirely within an inner periphery of the FSA in the plan view. For example, a first electrically-active metal line 48 in the first line level LL1, a second electrically-active metal line 48 in the second line level LL2, and a third electrically-active metal line 48 in the third line level LL3 may be located entirely within the inner periphery of the FSA in the plan view.

Referring collectively to FIGS. 1A - 3L, the first metal interconnect structures (40, 140) comprise first electrically-active metallic structures 40 and electrically-floating metallic structures 140. The first electrically-active metallic structures 40 may include electrically-active metal via structures 46 and electrically-active metal line structures 48. A first subset of the first metal interconnect structures (40, 140) may comprise a first vertically-extending electrically conductive path ECP1 comprising a first electrically-active metal via structure 46 at a first via level VL1. A second subset of the first metal interconnect structures (40, 140) comprises at least one electrically-floating metallic structure 140 formed within a frame-shaped area in a plan view. The at least one electrically-active metal via structure 46 may be located inside an inner periphery of the FSA in the plan view.

In one embodiment, the FSA may be a rectangular frame-shaped area that comprises an outer rectangular periphery coinciding with a subset of sidewalls of the at least one electrically-floating metallic structure 140. The rectangular frame-shaped area may further comprise an inner rectangular periphery coinciding with at least one vertically-extending edge of the at least one electrically-floating metallic structure 140. An entire area of the at least one electrically-floating metallic structure 140 may be formed within the rectangular frame-shaped area. The first electrically-active metal via structure 46 may be laterally offset inward from the inner rectangular periphery of the rectangular frame-shaped area.

The electrically-floating metallic structure 140 may comprise a contiguous set of multiple metallic structures that vertically extends over at least two line levels. In one embodiment, the at least two line levels comprise a first line level LL1 that overlies the first via level VL1 and a second line level LL2 that underlies the first via level VL1. In one embodiment, the at least one electrically-floating metallic structure 140 comprises a plurality of electrically-floating metallic structures 140 that are spaced apart from one another.

The at least one electrically-floating metallic structure 140 may comprise a frame-shaped interconnected metallic assembly 145 extending around a peripheral portion of the rectangular frame-shaped area in the plan view. In one embodiment, the frame-shaped interconnected metallic assembly 145 comprises a pair of first electrically-floating metal lines 148 laterally extending along a first horizontal direction hd1 and a pair of second electrically-floating metal lines 148 laterally extending along a second horizontal direction hd2. In one embodiment, the pair of first electrically-floating metal lines 148 are formed in a line level, such as the first line level LL1. The pair of second electrically-floating metal lines 148 may be formed in another line level, such as the second line level LL2. The frame-shaped interconnected metallic assembly 145 may further comprise four electrically-floating metal via structures 146 connecting a respective pair of a first electrically-floating metal line 148 and a second electrically-floating metal line 148 within a combination of the pair of first electrically-floating metal lines 148 and the pair of second electrically-floating metal lines 148. In one embodiment, the frame-shaped interconnected metallic assembly 145 comprises at least one first electrically-floating metal line 148 at the first line level LL1, at least one first electrically-floating metal via structure 146 at the first via level VL1, at least one first electrically-floating metal line 148 at the second line level LL2, at least one second electrically-floating metal via structure 146 at a second via level VL2, and at least one third electrically-floating metal line 148 at a third line level LL3.

In one embodiment, the at least one electrically-floating metallic structure 140 comprises a plurality of sidewall metal lines 148S that are arranged along sides of an outer rectangular periphery of the rectangular frame-shaped area in the plan view and laterally spaced apart from one another. In one embodiment, a first electrically-active metal line 48 and a second electrically-active metal line 48 may be formed entirely within an outer periphery of the rectangular frame-shaped area in the plan view. In one embodiment, the first electrically-active metal line 48 and the second electrically-active metal line 48 may laterally extend into the FSA in the plan view, and/or may extend outward from the outer periphery of the FSA.

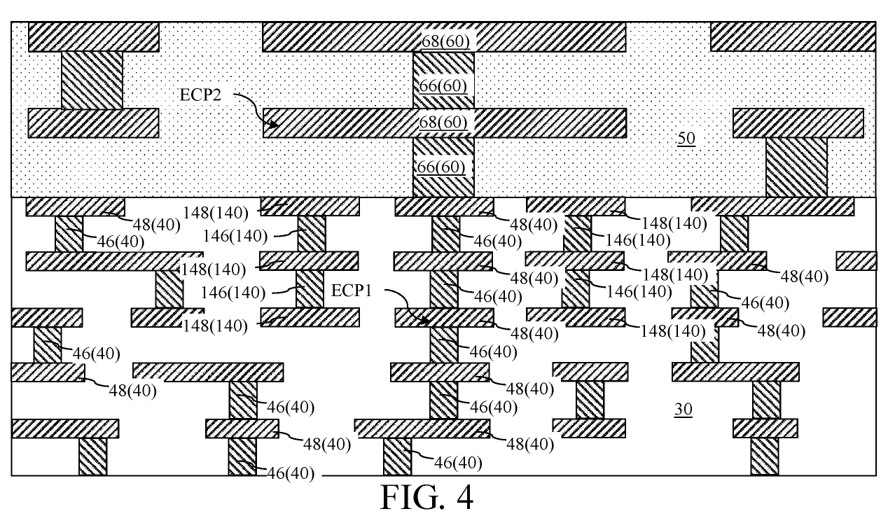

Referring to FIG. 4, second dielectric material layers 50 and additional metal interconnect structures are subsequently formed over the first dielectric material layers 30 and the first metal interconnect structures (40, 140). The additional metal interconnect structures may be referred to as upper-level metal interconnect structures or second metal interconnect structures in subsequent sections and/or in the claims. As noted above, ordinals such as “first” and “second” are only adjectives, and are not parts of element names.

The second dielectric material layers 50 may comprise, and/or may be composed primarily of, and/or may consist essentially of, non-porous silicate glass materials having a respective dielectric constant in a range from 3.4 to 3.9. For example, the second dielectric material layers 50 may comprise, and/or may be composed primarily of, and/or may consist essentially of, undoped silicate glass or a doped silicate glass (such as borosilicate glass, borophosphosilicate glass, or fluorosilicate glass). The total number of line levels within the second dielectric material layers 50 may be in a range from 1 to 6, such as from 2 to 3. A material layer is “composed primarily of” a dielectric material if more than 50 % of the entire volume of the material layer consists of the dielectric material.

The second metal interconnect structures in the second dielectric material layers 50 comprise second electrically-active metallic structures 60 that constitute components of a respective second electrically conductive path ECP2. The second electrically-active metallic structures 60 may comprise second electrically-active metal lines 68 (which are also referred to as upper electrically-active metal lines 68) and second electrically-active metal via structures 66 (which are also referred to upper electrically-active metal via structures).

According to an aspect of the present disclosure, each of the electrically-floating metallic structures 140 formed within the first dielectric material layers 30 are electrically floating after formation of the second dielectric material layers 50 comprise second electrically-active metallic structures 60. In one embodiment, topmost surfaces of the electrically-floating metallic structures 140 do not extend above the horizontal plane including the interface between the first dielectric material layers 30 and the second dielectric material layers 50. In one embodiment, bottommost surfaces of the electrically-floating metallic structures 140 are in contact with a respective underlying first dielectric material layer 30. In one embodiment, all surfaces of the electrically-floating metallic structures 140 may be in contact with the first dielectric material layers 30, the second dielectric material layers 50, or another electrically-floating metallic structure 140.

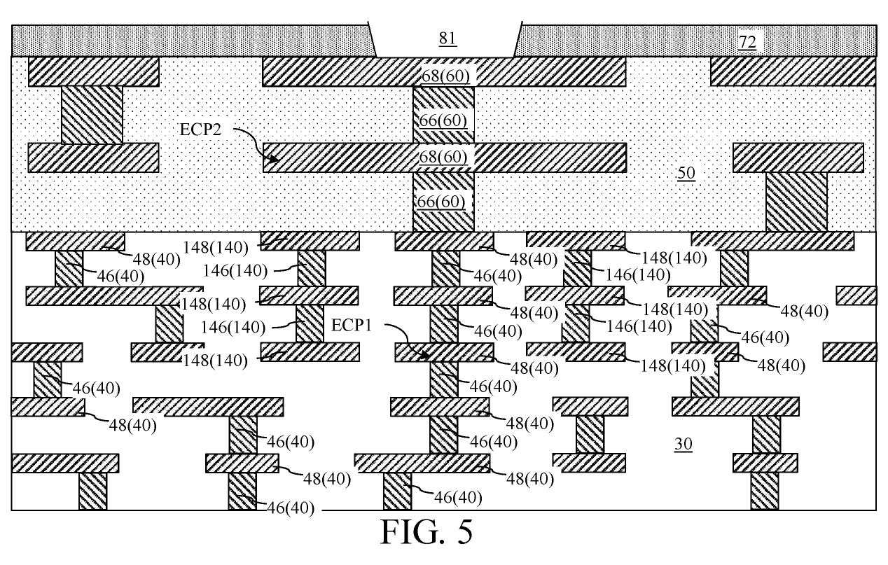

Referring to FIG. 5, a first dielectric passivation layer 72 may be formed over the second dielectric material layers 50. The first dielectric passivation layer 72 comprises a dielectric material that may effectively block diffusion of hydrogen, moisture, and metallic impurities. For example, the first dielectric passivation layer 72 may comprise, and/or may consist essentially of, silicon nitride or silicon carbonitride. The first dielectric passivation layer 72 may be formed, for example, by chemical vapor deposition. The thickness of the first dielectric passivation layer 72 may be in a range from 200 nm to 2,000 nm, although lesser or greater thicknesses may also be used. Pad openings 81 may be formed through the first dielectric passivation layer 72 over the topmost second electrically-active metal lines 68 of the second electrically conductive paths ECP2.

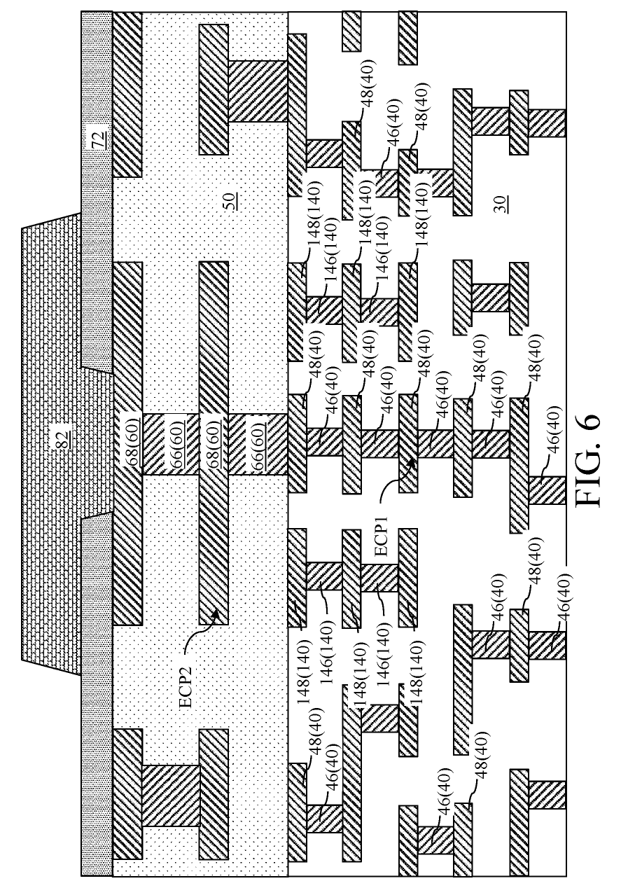

Referring to FIG. 6, at least one metallic material may be deposited over the first dielectric passivation layer 72, and may be patterned to form an array of bonding pads 82. The at least one metallic material may include a combination of at least one metallic liner material and at least one high-electrical-conductivity metal. Exemplary metallic liner materials include TiN, TaN, WN, and/or MoN. Exemplary high-electrical-conductivity metals include copper, aluminum, and alloys thereof. The at least one metallic liner material may be deposited by physical vapor deposition (PVD) or chemical vapor deposition (CVD), and may have a thickness in a range from 20 nm to 200 nm, although lesser or greater thicknesses may also be used. The at least one high-electrical-conductivity metal may be deposited by PVD or CVD, and may have a thickness in a range from 500 nm to 5,000 nm, although lesser or greater thicknesses may also be used.

The at least one metallic material of the bonding pads 82 may be patterned, for example, by applying and lithographically patterning a photoresist layer over the deposited at least one metallic material, and by transferring the pattern in the photoresist layer through the at least one metallic material using at least one etch process, which may comprise at least one anisotropic etch process. The patterned photoresist layer may be subsequently removed, for example, by ashing. The remaining portions of the at least one metallic material constitutes the bonding pads 82. In one embodiment, the bonding pads 82 may be formed as a two-dimensional periodic array of bonding pads 82. The lateral dimensions (such as a width and a length, or a diameter) of the bonding pads 82 may be in a range from 20 μm to 200 μm, although lesser or greater lateral dimensions may also be used. The bonding pads 82 may be designed to accommodate controlled collapse chip connection (C4) bonding processes to be subsequently performed. In some embodiments, the bonding pads 82 may have a circular shape to promote uniform solder wetting and bump formation, while in other instances, they bonding pads 82 have a square or rectangular shape to maximize the bonding area within the available space on the chip surface.

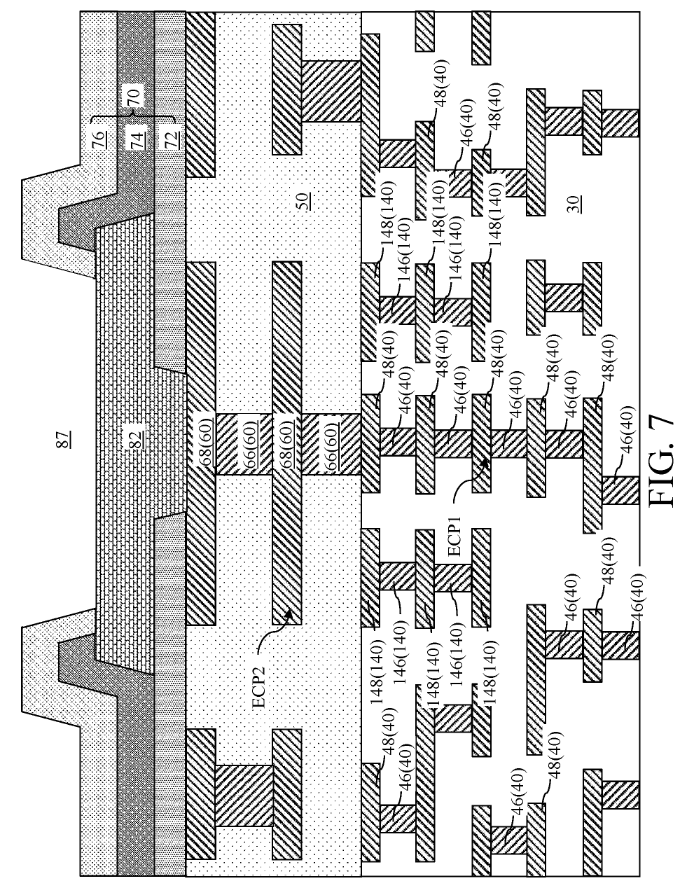

Referring to FIG. 7, a second dielectric passivation layer 74 may be formed over the bonding pads 82 and the first dielectric passivation layer 72. The second dielectric passivation layer 74 comprises a dielectric material that may effectively block diffusion of hydrogen, moisture, and metallic impurities. For example, the second dielectric passivation layer 74 may comprise silicon nitride or silicon carbonitride. The second dielectric passivation layer 74 may be formed, for example, by chemical vapor deposition. The thickness of the second dielectric passivation layer 74 may be in a range from 200 nm to 2,000 nm, although lesser or greater thicknesses may also be used. Openings may be formed through the second dielectric passivation layer 74 over the center portion of each bonding pad 82, for example, by performing a combination of lithographic patterning a lithographic patterning process and an anisotropic etch process.

A third dielectric passivation layer 76 may be formed over second dielectric passivation layer 74. The third dielectric passivation layer 74 comprises, and/or consists essentially of, at least one polymer dielectric material such as polyimide, benzocyclobutene (BCB), or polybenzoxazole (PBO). The third dielectric passivation layer 76 may be formed by spin coating, spray coating, or other suitable deposition methods. The thickness of the third dielectric passivation layer 76 may be in a range from 1 μm to 20 μm, although lesser or greater thicknesses may also be used. Openings 87 may be formed through the third dielectric passivation layer 76 over the center portion of each bonding pad 82, for example, by performing a combination of lithographic patterning and an anisotropic etch process.

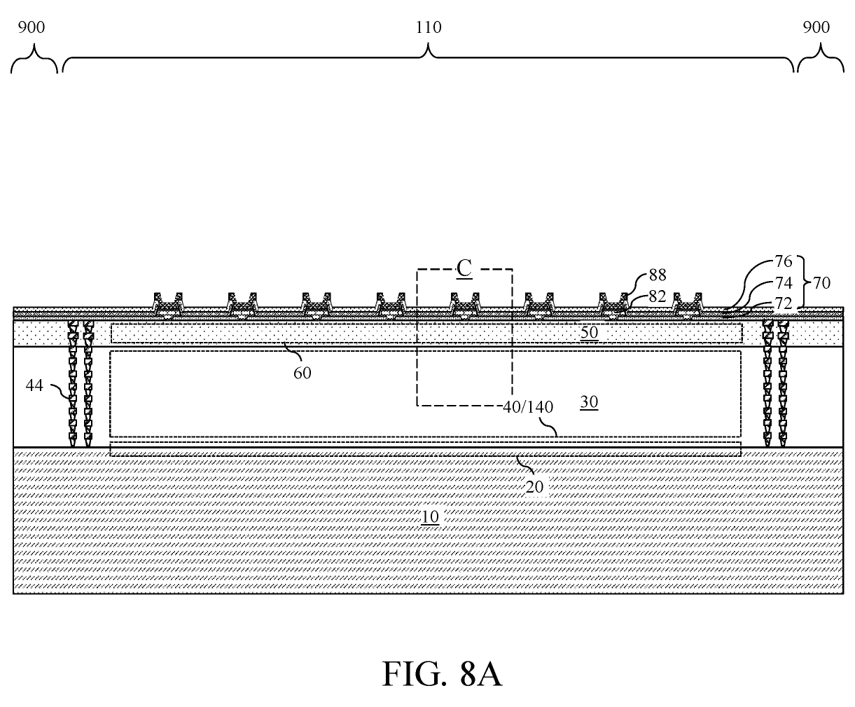

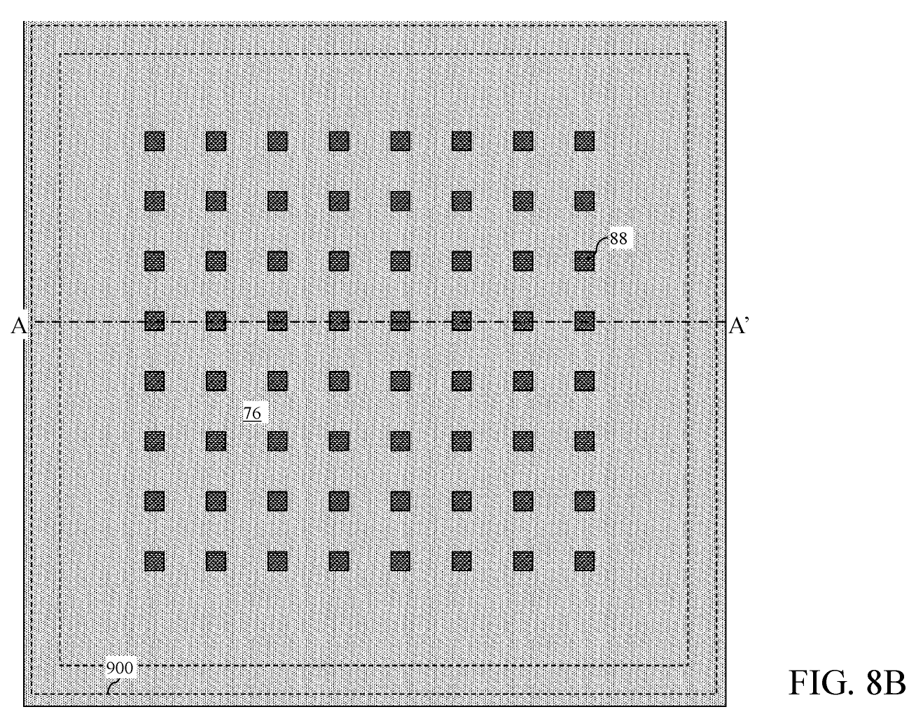

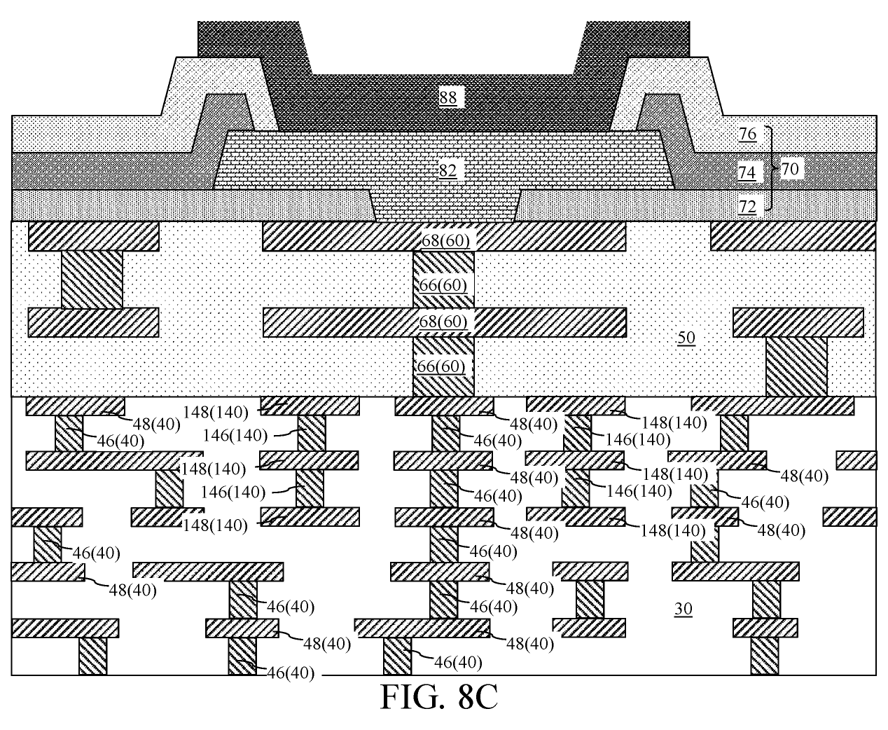

Referring to FIGS. 8A - 8C, underbump metallization pads 88 may be formed in each opening 87 overlying the bonding pads 82. For example, a layer stack of underbump metallization material layers may be deposited on the physically exposed top surface segments of the bonding pads 82 and over the dielectric passivation layers 70. The layer stack of underbump metallization material layers may include multiple metallic layers with different compositions and functions. For example, the layer stack may comprise an adhesion layer, a diffusion barrier layer, and a wetting layer. The adhesion layer may include materials such as titanium, chromium, or tantalum, and may have a thickness in a range from 10 nm to 100 nm. The diffusion barrier layer may include materials such as titanium nitride, tantalum nitride, or tungsten nitride, and may have a thickness in a range from 20 nm to 200 nm. The wetting layer may include materials such as copper, nickel, or gold, and may have a thickness in a range from 50 nm to 500 nm.

The underbump metallization material layers may be deposited using various deposition methods. For example, physical vapor deposition (PVD) methods such as sputtering or evaporation may be used. Alternatively or additionally, chemical vapor deposition (CVD) or atomic layer deposition (ALD) methods may be used. Alternatively or additionally. Electroless plating or electroplating processes may also be utilized for depositing certain layers, especially the wetting layer.

The underbump metallization material layers may be subsequently patterned into underbump metallization pads 88. For example, a photoresist layer (not illustrated) may be applied over the deposited underbump metallization material layers, and may be lithographically patterned. The pattern in the photoresist layer may then be transferred to the underlying underbump metallization material layers by performing one or more etch processes. The one or more etch processes may include wet etching, dry etching, or a combination of both, depending on the materials being etched and the desired profile of the underbump metallization pads 88. The photoresist layer may be subsequently removed, for example, by using a resist stripping solution or a plasma ashing process.

The underbump metallization pads 88 may have lateral dimensions larger than the openings 87 in the third dielectric passivation layer 76, Thus, a peripheral portion of each underbump metallization pad 88 may have an areal overlap with portions of the second dielectric passivation layer 74 and the third dielectric passivation layer 76 overlying peripheral portions of the bonding pads 82. The thickness of the underbump metallization pads 88 may be in a range from 0.5 μm to 5 μm, although lesser or greater thicknesses may also be used.

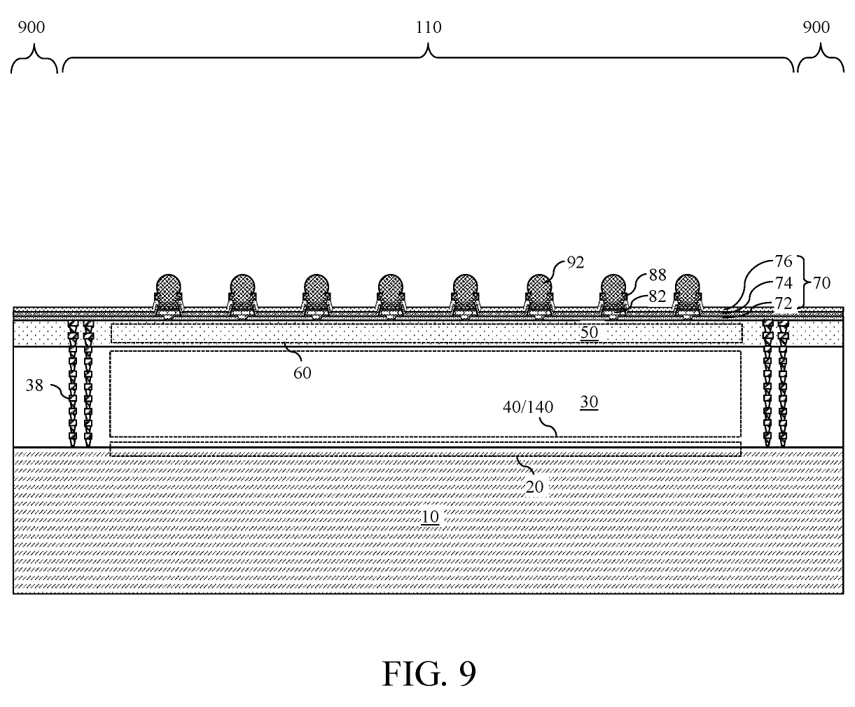

Referring to FIG. 9, solder material portions 92 may be applied to each of the underbump metallization pads 88. Thus, a two-dimensional array of solder material portions 92 may be formed on the two-dimensional array of underbump metallization pads 88, which may be a two-dimensional array of controlled-collapse chip connection (C4) pads.

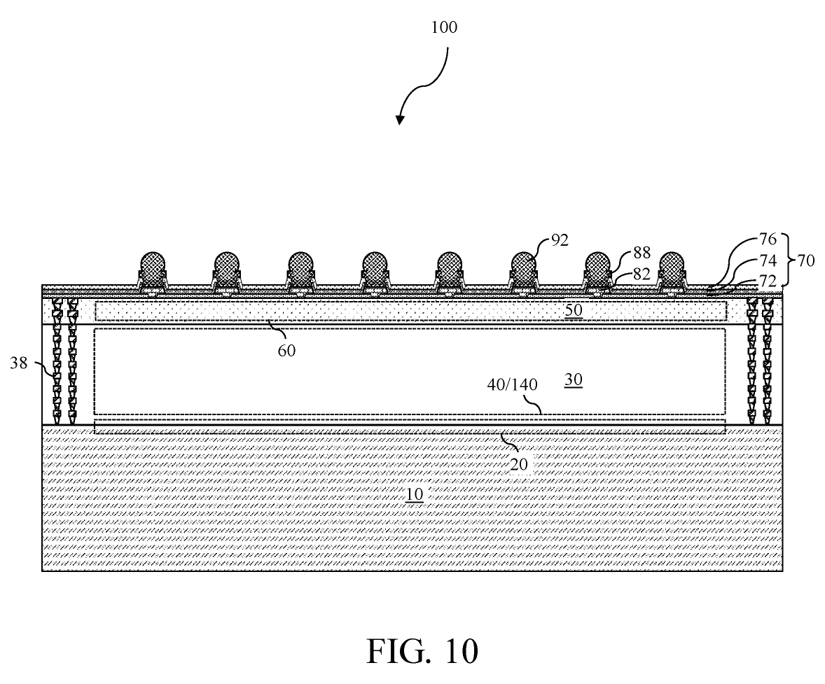

Referring to FIG. 10, the semiconductor substrate 10 of the wafer 1000 may be thinned from the backside. The thinning of the semiconductor substrate 10 may be effected by grinding, polishing, an isotropic etch process, and/or an anisotropic etch process. The thickness of the semiconductor substrate 10 after the thinning process may be in a range from 10 microns to 60 microns, although lesser and greater thicknesses may also be used.

Subsequently, the wafer 1000 may be diced along the dicing channels. The materials in the dicing channel regions 900 may be removed during the dicing process. Remaining discrete portions of the wafer 1000 after the dicing process comprise materials of the semiconductor die regions 110. Each semiconductor die region 110 that remains after the dicing process constitutes a semiconductor die 100.

Generally, a wafer 1000 including a passivation layer stack, first dielectric material layers 30, metal interconnect structures (40, 140), semiconductor devices 20, and a semiconductor substrate 10 may be diced after formation of the underbump metallization pads 88 along dicing channels into a plurality of semiconductor dies 100. Each semiconductor die 100 comprises a diced portion of the semiconductor substrate 10, which is herein referred to as a semiconductor substrate 10 of the semiconductor die 100.

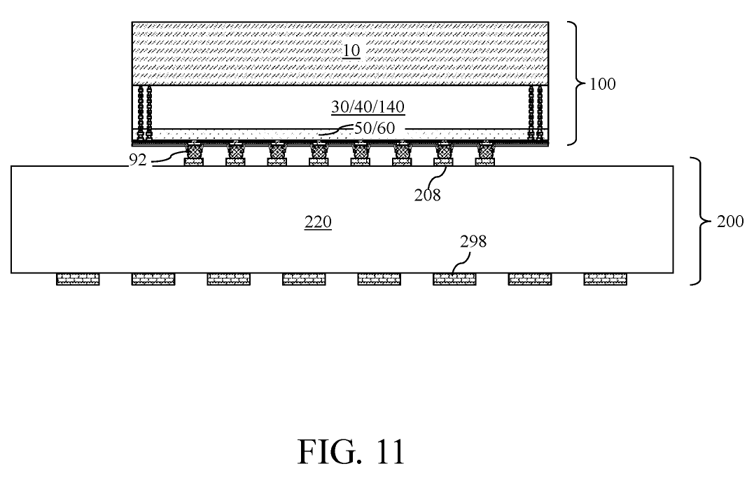

Referring to FIG. 11, a semiconductor die 100 may be bonded to a packaging substrate 200. Generally, the packaging structure is a packaging substrate 200, which may be any type of packaging substrate known in the art. For example, the packaging substrate 200 may be a cored packaging substrate, a coreless packaging substrate, or a ceramic packaging substrate. Alternatively, the packaging substrate 200 may comprise a system-on-integrated packaging substrate (SoIS) including redistribution layers and/or dielectric interlayers, at least one embedded interposer (such as a silicon interposer). The packaging substrate 200 comprises a substrate body 220, a two-dimensional array of substrate bump structures 208 on a proximal side of the substrate body 220, and a two-dimensional array of bonding pads 298 (such as C4 bonding pads) on a distal side of the substrate body 220. The two-dimensional array of substrate bump structures 208 may have the same pitch as the two-dimensional array of underbump metallization pads 88.

The semiconductor die 100 may be bonded to the packaging substrate 200 by positioning the array of solder material portions 92 on the two-dimensional array of substrate bump structures 208, and by inducing reflow of the solder material portions 92. The semiconductor die 100 may be any of the semiconductor dies 100 described above. A bonded assembly of the semiconductor die 100 and the packaging substrate 200 is provided.

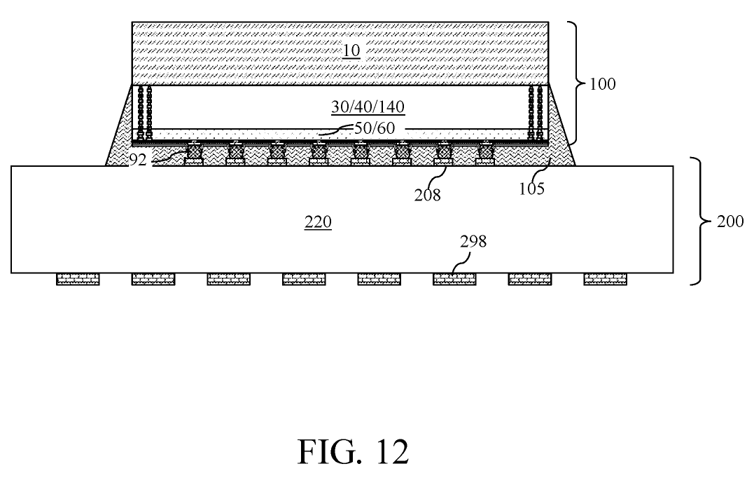

Referring to FIG. 12, an underfill material may be applied around the array of solder material portions 92 to form an underfill material portion 105. The mechanical stress generated during application of the underfill material and applied to the semiconductor die 100 is partially absorbed by the electrically-floating metallic structures 140 formed within the first dielectric material layers 30 through deformation and/or displacement of the electrically-floating metallic structures 140. Thus, deformation and/or displacement of the first electrically-active metallic structures 40 within the first dielectric material layers 30 may be reduced.

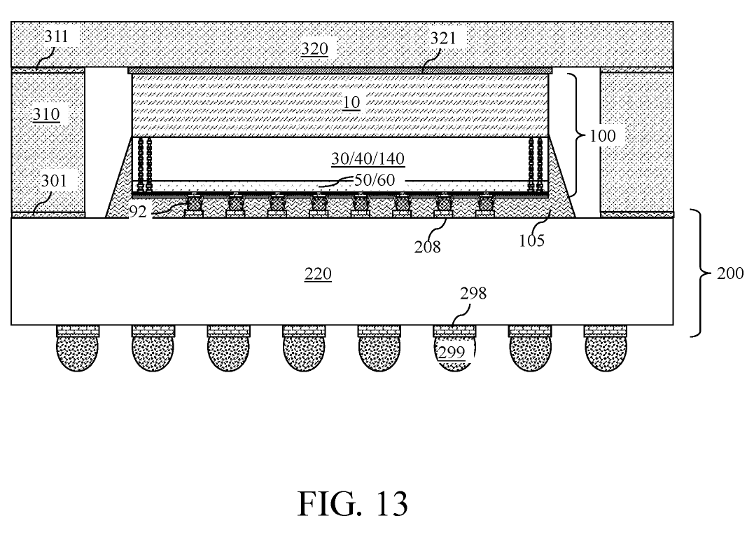

Referring to FIG. 13, a first adhesive layer 301 may be applied to a proximal horizontal surface of the packaging substrate 200. A stiffener ring 310 may be attached to the first adhesive layer 301. A second adhesive layer 311 may be applied to the top surface of the stiffener ring 310. A thermal interface material (TIM) layer 321 may be applied to the backside of the semiconductor substrate 10. A lid structure 320 may be attached to the second adhesive layer 311 and the TIM layer 321. Solder balls 299 may be attached to the bonding pads 298. A first semiconductor package is provided.

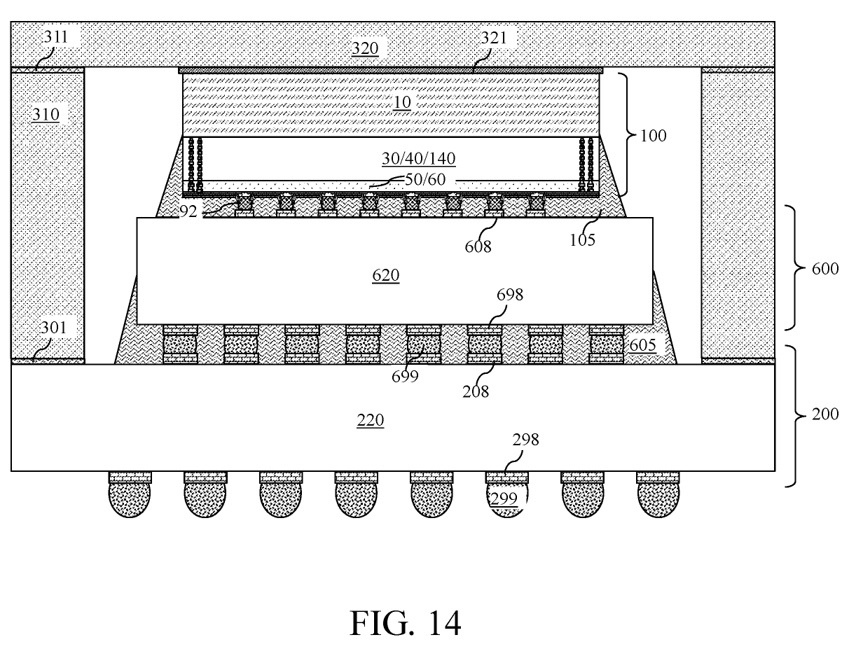

Referring to FIG. 14, a second semiconductor package is illustrated, in which an interposer 600 is attached to a semiconductor die 100 prior to attachment to a packaging substrate 200. The interposer 600 may comprise an organic interposer, a semiconductor interposer, a ceramic interposer, or any other type of interposer known in the art. The interposer 600 comprises an interposer body 620, an array of interposer bump structures 608 located on a proximal side of the interposer body 620 and having a same pitch as the array of underbump metallization pads 88, and a two-dimensional array of interposer bonding structures 698 located on a distal side of the interposer body 620 and having a same pitch as the two-dimensional array of substrate bump structures 208.

In this embodiment, the semiconductor die 100 may be attached to the interposer 600 through the array of solder material portions 92 (which provide bonding through reflow and re-solidification), and an underfill material portion 105 may be applied around the array of solder material portions 92. As discussed above, the mechanical stress generated during application of the underfill material and applied to the semiconductor die 100 is partially absorbed by the electrically-floating metallic structures 140 embedded within the first dielectric material layers 30 through deformation and/or displacement of the electrically-floating metallic structures 140. Subsequently, the assembly of the semiconductor die 100 and the interposer 600 may be attached to a packaging substrate 200 through an additional array of solder material portions 699. An additional underfill material portion 605 may be formed around the additional array of solder material portions 699. Subsequently, mechanical stabilization structures (310, 320) may be attached to the packaging substrate 200 and the semiconductor die 100.

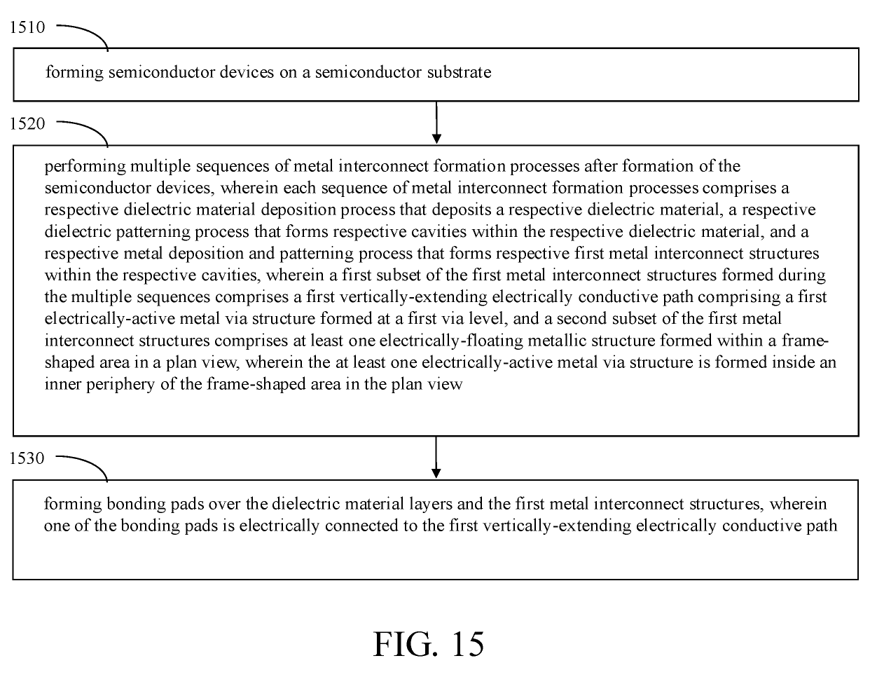

Referring to FIG. 15, a first sequence of processing steps for forming a device structure is illustrated.

Referring to step 1510 and FIG. 1A - 1D, semiconductor devices 20 may be formed on a semiconductor substrate 10.

Referring to step 1520 and FIGS. 1A - 3L, multiple sequences of metal interconnect formation processes may be performed after formation of the semiconductor devices 20. Each sequence of metal interconnect formation processes comprises a respective dielectric material deposition process that deposits a respective dielectric material, a respective dielectric patterning process that forms respective cavities within the respective dielectric material, and a respective metal deposition and patterning process that forms respective first metal interconnect structures (40, 140) within the respective cavities. A first subset of the first metal interconnect structures (40, 140) formed during the multiple sequences comprises a first vertically-extending electrically conductive path ECP1 comprising a first electrically-active metal via structure 46 formed at a first via level VL1. A second subset of the first metal interconnect structures (40, 140) comprises at least one electrically-floating metallic structure 140 formed within a FSA in a plan view. The at least one electrically-active metal via structure 46 is located at a center portion of the FSA in the plan view.

In one embodiment, the first dielectric material layers 30 deposited during the multiple sequences comprise a respective dielectric material having a respective dielectric constant that is greater than 1.0 and is less than 3.0. In one embodiment, the electrically-floating metallic structure 140 comprises a contiguous set of multiple metallic structures (146, 148) that vertically extends over at least two line levels, the at least two line levels comprising a first line level LL1 that overlies the first via level VL1 and a second line level LL2 that underlies the first via level VL1.

In one embodiment, the FSA comprises an outer rectangular periphery coinciding with a subset of sidewalls of the at least one electrically-floating metallic structure 140 and further comprises an inner rectangular periphery coinciding with at least one vertically-extending edge of the at least one electrically-floating metallic structure 140; an entire area of the at least one electrically-floating metallic structure 140 is formed within the FSA; and the first electrically-active metal via structure 46 is laterally offset inward from the inner rectangular periphery of the FSA. In one embodiment, the at least one electrically-floating metallic structure 140 comprises a plurality of electrically-floating metallic structures 140 that are spaced apart from one another.

In one embodiment, the at least one electrically-floating metallic structure 140 comprises a frame-shaped interconnected metallic assembly 145 extending around a peripheral portion of the FSA in the plan view. In one embodiment, the frame-shaped interconnected metallic assembly 145 comprises: a pair of first electrically-floating metal lines 148 laterally extending along a first horizontal direction hd1; and a pair of second electrically-floating metal lines 148 laterally extending along a second horizontal direction hd2. In one embodiment, the pair of first electrically-floating metal lines 148 are formed in a line level (such as a first line level LL1); the pair of second electrically-floating metal lines 148 are formed in another line level (such as a second line level LL2); and the frame-shaped interconnected metallic assembly 145 further comprises four electrically-floating metal via structures 146 connecting a respective pair of a first electrically-floating metal line 148 and a second electrically-floating metal line 148 within a combination of the pair of first electrically-floating metal lines 148 and the pair of second electrically-floating metal lines 148. In one embodiment, the at least one electrically-floating metallic structure 140 comprises a plurality of sidewall metal lines 148S that are arranged along sides of an outer rectangular periphery of the FSA in the plan view and laterally spaced apart from one another.

Referring to step 1530 and FIGS. 4 - 14, bonding pads 88 may be formed over the first dielectric material layers 30 and the first metal interconnect structures (40, 140). One of the bonding pads 88 is electrically connected to the first vertically-extending electrically conductive path ECP1.

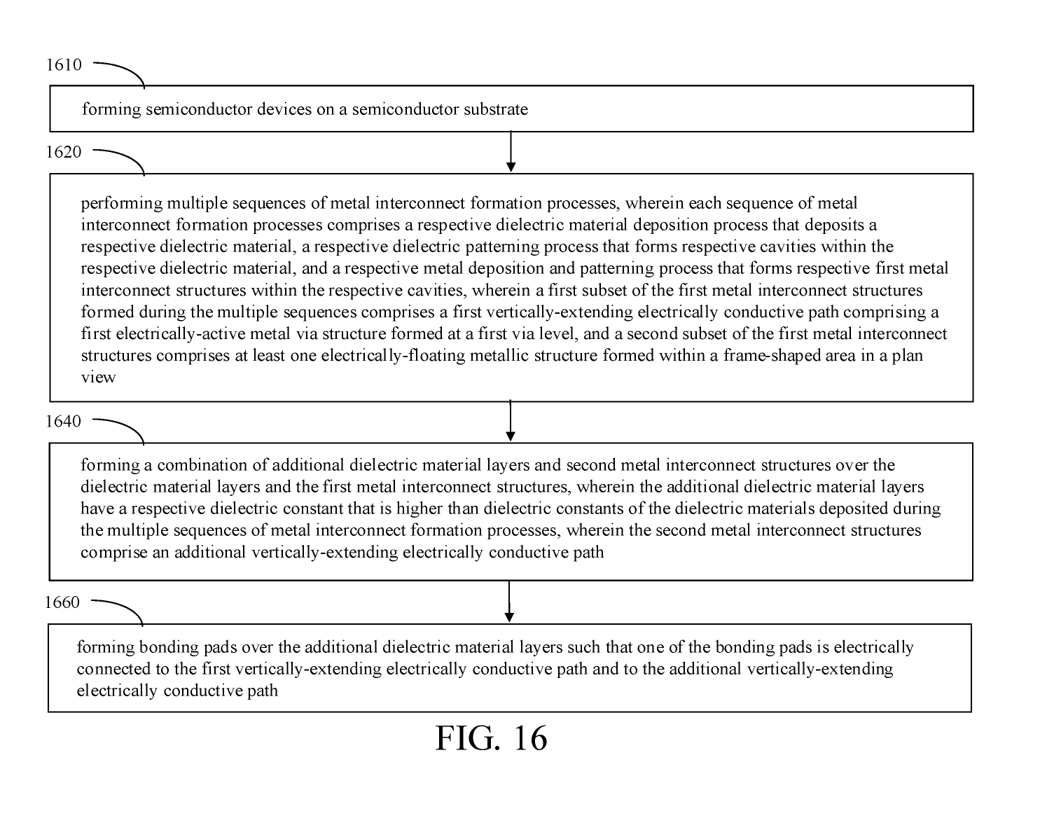

Referring to FIG. 16, a second sequence of processing steps for forming a device structure is illustrated.

Referring to step 1610 and FIG. 1A - 1D, semiconductor devices 20 may be formed on a semiconductor substrate 10.

Referring to step 1620 and FIGS. 1A - 3L, multiple sequences of metal interconnect formation processes. Each sequence of metal interconnect formation processes comprises a respective dielectric material deposition process that deposits a respective dielectric material, a respective dielectric patterning process that forms respective cavities within the respective dielectric material, and a respective metal deposition and patterning process that forms respective first metal interconnect structures (40, 140) within the respective cavities. A first subset of the first metal interconnect structures (40, 140) formed during the multiple sequences comprises a first vertically-extending electrically conductive path ECP1 comprising a first electrically-active metal via structure 46 formed at a first via level VL1, and a second subset of the first metal interconnect structures (40, 140) comprises at least one electrically-floating metallic structure 140 formed within a FSA in a plan view.

In one embodiment, the first dielectric material layers 30 deposited during the multiple sequences comprise a respective dielectric material having a respective dielectric constant that is greater than 1.0 and is less than 3.0; and the additional dielectric material layers (such as the second dielectric material layers 50) comprise a respective silicon-oxide-based dielectric material having a dielectric constant in a range from 3.4 to 3.9. In one embodiment, the first vertically-extending electrically conductive path ECP1 comprises: a first electrically-active metal line 48 the is formed on the first electrically-active metal via structure 46; and a second electrically-active metal line 49 on which the first electrically-active metal via structure 46 is formed. In one embodiment, the first electrically-active metal line 48 and the second electrically-active metal line 48 are formed entirely within an outer periphery of the FSA in the plan view.

In one embodiment, the at least one electrically-floating metallic structure 140 comprises a frame-shaped interconnected metallic assembly 145 comprising at least one first electrically-floating metal line 148 formed at a first line level LL1, at least one first electrically-floating metal via structure 146 formed at the first via level VL1, at least one first electrically-floating metal line 148 formed at a second line level LL2, at least one second electrically-floating metal via structure 146 formed at a second via level, and at least one third electrically-floating metal line 148 formed at a third line level.

Referring to step 1640 and FIGS. 4 and 5, a combination of additional dielectric material layers (such as second dielectric material layers 50) and second metal interconnect structures 60 may be formed over the first dielectric material layers 30 and the first metal interconnect structures (40, 140). The additional dielectric material layers (such as the second dielectric material layers 50) have a respective dielectric constant that is higher than dielectric constants of the dielectric materials deposited during the multiple sequences of metal interconnect formation processes, wherein the second metal interconnect structures 60 comprise an additional vertically-extending electrically conductive path (such as a second vertically-extending electrically conductive path ECP2).

Referring to step 1660 and FIGS. 6 - 13, bonding pads 88 may be formed over the additional dielectric material layers such that one of the bonding pads 88 is electrically connected to the first vertically-extending electrically conductive path ECP1 and to the additional vertically-extending electrically conductive path (such as the second vertically-extending electrically conductive path ECP2). In one embodiment., at least one dielectric passivation layer 70 may be formed over the additional dielectric material layers 50. An array of openings 87 may be formed through the at least one dielectric passivation layer 70. The underbump metallization pads 88 are formed within the array of openings 87.

Referring to all drawings and according to various embodiments of the present disclosure, a device structure is provided, which comprises: semiconductor devices 20 located on a semiconductor substrate 10; first metal interconnect structures (40, 140) located in first dielectric material layers 30 that overlie the semiconductor devices 20, wherein a first subset of the first metal interconnect structures (40, 140) comprises a first vertically-extending electrically conductive path ECP1 comprising a first electrically-active metal via structure 46 located at a first via level VL1, and a second subset of the first metal interconnect structures (40, 140) comprises at least one electrically-floating metallic structure 140 located at four corner regions of a FSA in a plan view, wherein the at least one electrically-active metal via structure 46 is located at a center portion of the FSA in the plan view; and bonding pads 88 overlying the first dielectric material layers 30 and the first metal interconnect structures (40, 140), wherein one of the bonding pads 88 is electrically connected to the first vertically-extending electrically conductive path ECP1.

In one embodiment, the first dielectric material layers 30 comprise a respective dielectric material having a respective dielectric constant that is greater than 1.0 and is less than 3.0. In one embodiment, the FSA comprises an outer rectangular periphery coinciding with a subset of sidewalls of the at least one electrically-floating metallic structure 140 and further comprises an inner rectangular periphery coinciding with at least one vertically-extending edge of the at least one electrically-floating metallic structure 140; an entire area of the at least one electrically-floating metallic structure 140 is located within the FSA; and the first electrically-active metal via structure 46 is laterally offset inward from the inner rectangular periphery of the FSA.

In one embodiment, the at least one electrically-floating metallic structure 140 comprises a frame-shaped interconnected metallic assembly 145 extending around a peripheral portion of the FSA in the plan view. In one embodiment, the device structure comprises second metal interconnect structures 60 located within second dielectric material layers 50 that overlie the first dielectric material layers 30. Each of the second dielectric material layers 50 has a respective dielectric constant that is higher than dielectric constants of dielectric materials within the first dielectric material layers 30; and each of the bonding pads 88 is electrically connected to a respective one of the first metal interconnect structures (40, 140) through a respective subset of the second metal interconnect structures 60.

Embodiments of the present disclosure use electrically-floating metallic structures 140 around first electrically conductive paths ECP1 to reduce mechanical stress on the electrically-active metallic structures of the first electrically conductive paths ECP1. In embodiments in which the first dielectric material layers 30 comprise extreme low-k (ELK) dielectric materials including cavities therein, the reduction in the mechanical stress may be particularly beneficial for enhancing the reliability of the first electrically conductive paths ECP1. The electrically-floating metallic structures 140 may be advantageously used mitigate the risk of via cracking in the electrically-active metallic structures 40 of the first electrically conductive paths ECP1 through the first dielectric material layers 30, particularly in the embodiments in which ELK dielectric materials are used for the first dielectric material layers 30.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of forming a device structure, comprising:
forming semiconductor devices on a semiconductor substrate;
performing multiple sequences of metal interconnect formation processes after formation of the semiconductor devices, wherein each sequence of metal interconnect formation processes comprises a respective dielectric material deposition process that deposits a respective dielectric material layer, a respective dielectric patterning process that forms respective cavities within the respective dielectric material layer, and a respective metal deposition and patterning process that forms respective first metal interconnect structures within the respective cavities, wherein a first subset of the first metal interconnect structures formed during the multiple sequences comprises a first vertically-extending electrically conductive path comprising at least one first electrically-active metal via structure formed at a first via level, and a second subset of the first metal interconnect structures comprises at least one electrically-floating metallic structure formed within a frame-shaped area in a plan view, wherein the at least one electrically-active metal via structure is formed inside an inner periphery of the frame-shaped area in the plan view; and
forming bonding pads over the dielectric material layers and the first metal interconnect structures, wherein one of the bonding pads is electrically connected to the first vertically-extending electrically conductive path.

2. The method of claim 1, wherein the dielectric material layers deposited during the multiple sequences comprise a respective dielectric material having a respective dielectric constant that is greater than 1.0 and is less than 3.0.

3. The method of claim 1, wherein the electrically-floating metallic structure comprises a contiguous set of multiple metallic structures that vertically extends over at least two line levels, the at least two line levels comprising a first line level that overlies the first via level and a second line level that underlies the first via level.

4. The method of claim 1, wherein:
the frame-shaped area comprises an outer rectangular periphery coinciding with a subset of sidewalls of the at least one electrically-floating metallic structure and further comprises an inner rectangular periphery coinciding with at least one vertically-extending edge of the at least one electrically-floating metallic structure;
an entire area of the at least one electrically-floating metallic structure is formed within the frame-shaped area; and
the first electrically-active metal via structure is laterally offset inward from the inner rectangular periphery of the frame-shaped area.

5. The method of claim 1, wherein the at least one electrically-floating metallic structure comprises a plurality of electrically-floating metallic structures that are spaced apart from one another.

6. The method of claim 1, wherein the at least one electrically-floating metallic structure comprises a frame-shaped interconnected metallic assembly extending around a peripheral portion of the frame-shaped area in the plan view.

7. The method of claim 6, wherein the frame-shaped interconnected metallic assembly comprises:
a pair of first electrically-floating metal lines laterally extending along a first horizontal direction; and
a pair of second electrically-floating metal lines laterally extending along a second horizontal direction.

8. The method of claim 7, wherein:
the pair of first electrically-floating metal lines are formed in a line level;
the pair of second electrically-floating metal lines are formed in another line level; and
the frame-shaped interconnected metallic assembly further comprises four electrically-floating metal via structures connecting a respective pair of a first electrically-floating metal line and a second electrically-floating metal line within a combination of the pair of first electrically-floating metal lines and the pair of second electrically-floating metal lines.

9. The method of claim 1, wherein the at least one electrically-floating metallic structure comprises a plurality of sidewall metal lines that are arranged along sides of an outer rectangular periphery of the frame-shaped area in the plan view and laterally spaced apart from one another.

10. A method of forming a device structure, comprising:
forming semiconductor devices on a semiconductor substrate;
performing multiple sequences of metal interconnect formation processes, wherein each sequence of metal interconnect formation processes comprises a respective dielectric material deposition process that deposits a respective dielectric material, a respective dielectric patterning process that forms respective cavities within the respective dielectric material, and a respective metal deposition and patterning process that forms respective first metal interconnect structures within the respective cavities, wherein a first subset of the first metal interconnect structures formed during the multiple sequences comprises a first vertically-extending electrically conductive path comprising a first electrically-active metal via structure formed at a first via level, and a second subset of the first metal interconnect structures comprises at least one electrically-floating metallic structure formed within a frame-shaped area in a plan view;
forming a combination of additional dielectric material layers and second metal interconnect structures over the dielectric material layers and the first metal interconnect structures, wherein the additional dielectric material layers have a respective dielectric constant that is higher than dielectric constants of the dielectric materials deposited during the multiple sequences of metal interconnect formation processes, wherein the second metal interconnect structures comprise an additional vertically-extending electrically conductive path; and
forming bonding pads over the additional dielectric material layers such that one of the bonding pads is electrically connected to the first vertically-extending electrically conductive path and to the additional vertically-extending electrically conductive path.

11. The method of claim 10, wherein:
the dielectric material layers deposited during the multiple sequences comprise a respective dielectric material having a respective dielectric constant that is greater than 1.0 and is less than 3.0; and
the additional dielectric material layers comprise a respective silicon-oxide-based dielectric material having a dielectric constant in a range from 3.4 to 3.9.

12. The method of claim 10, further comprising:
forming at least one dielectric passivation layer over the additional dielectric material layers;
forming an array of openings through the at least one dielectric passivation layer; and
forming underbump metallization pads within the array of openings.

13. The method of claim 10, wherein the first vertically-extending electrically conductive path comprises:
a first electrically-active metal line that is formed on the first electrically-active metal via structure; and
a second electrically-active metal line on which the first electrically-active metal via structure is formed.

14. The method of claim 13, wherein the first electrically-active metal line and the second electrically-active metal line are formed entirely within an outer periphery of the frame-shaped area in the plan view.

15. The method of claim 10, wherein the at least one electrically-floating metallic structure comprises a frame-shaped interconnected metallic assembly comprising at least one first electrically-floating metal line formed at a first line level, at least one first electrically-floating metal via structure formed at the first via level, at least one first electrically-floating metal line formed at a second line level, at least one second electrically-floating metal via structure formed at a second via level, and at least one third electrically-floating metal line formed at a third line level.

16. A device structure comprising:
semiconductor devices located on a semiconductor substrate;
first metal interconnect structures located in first dielectric material layers that overlie the semiconductor devices, wherein a first subset of the first metal interconnect structures comprises a first vertically-extending electrically conductive path comprising at least one electrically-active metal via structure located at a first via level, and a second subset of the first metal interconnect structures comprises at least one electrically-floating metallic structure located within a frame-shaped area in a plan view, wherein the at least one electrically-active metal via structure is located at a center portion of the frame-shaped area in the plan view; and
bonding pads overlying the first dielectric material layers and the first metal interconnect structures, wherein one of the bonding pads is electrically connected to the first vertically-extending electrically conductive path.

17. The device structure of claim 16, wherein the first dielectric material layers comprise a respective dielectric material having a respective dielectric constant that is greater than 1.0 and is less than 3.0.

18. The device structure of claim 16, wherein:
the frame-shaped area comprises an outer rectangular periphery coinciding with a subset of sidewalls of the at least one electrically-floating metallic structure and further comprises an inner rectangular periphery coinciding with at least one vertically-extending edge of the at least one electrically-floating metallic structure;
an entire area of the at least one electrically-floating metallic structure is located within the frame-shaped area; and
the first electrically-active metal via structure is laterally offset inward from the inner rectangular periphery of the frame-shaped area.

19. The device structure of claim 16, wherein the at least one electrically-floating metallic structure comprises a frame-shaped interconnected metallic assembly extending around a peripheral portion of the frame-shaped area in the plan view.

20. The device structure of claim 16, further comprising second metal interconnect structures located within second dielectric material layers that overlie the first dielectric material layers, wherein:
each of the second dielectric material layers has a respective dielectric constant that is higher than dielectric constants of dielectric materials within the first dielectric material layers; and
each of the bonding pads is electrically connected to a respective one of the first metal interconnect structures through a respective subset of the second metal interconnect structures.
